(19) United States
(12) Patent Application Publication
(10) Pub. No.: US 2024/0280518 A1
(43) Pub. Date: Aug. 22, 2024

(54) ANALYSIS METHOD OF PHOTOSENSITIVE COMPOSITION, PRODUCTION METHOD OF PHOTOSENSITIVE COMPOSITION, AND MANUFACTURING METHOD OF ELECTRONIC DEVICE

(71) Applicant: FUJIFILM Corporation, Tokyo (JP)

(72) Inventors: Hideo NAGASAKI, Haibara-gun (JP); Tetsuya KAMIMURA, Haibara-gun (JP)

(73) Assignee: FUJIFILM Corporation, Tokyo (JP)

(21) Appl. No.: 18/611,037

(22) Filed: Mar. 20, 2024

Related U.S. Application Data
(63) Continuation of application No. PCT/JP2022/032965, filed on Sep. 1, 2022.

(30) Foreign Application Priority Data
Sep. 29, 2021 (JP) 2021-159403
Mar. 24, 2022 (JP) 2022-048322

(51) Int. Cl. G01N 23/223; G03F 7/00; G03F 7/038; G03F 7/039; G03F 7/32; G03F 7/36

(52) U.S. Cl. CPC G01N 23/223; G03F 7/0002; G03F 7/32; G03F 7/36; G03F 7/70616; G03F 7/706847; G03F 7/038; G03F 7/039

(57) ABSTRACT

Provided are an analysis method of a photosensitive composition, with which a trace amount of metal atoms contained in the photosensitive composition can be easily detected, a production method of a photosensitive composition, and a manufacturing method of an electronic device. The analysis method of a photosensitive composition includes a step 1 of applying a photosensitive composition onto a substrate to form a coating film, a step 2 of removing the coating film from the substrate without exposing the coating film to obtain a coating film-removed substrate, and a step 3 of measuring the number of metal atoms per unit area on the coating film-removed substrate by a total reflection X-ray fluorescence analysis method to obtain a measured value.

### CROSS-REFERENCE TO RELATED APPLICATIONS

This application is a Continuation of PCT International Application No. PCT/JP2022/032965 filed on Sep. 1, 2022, which claims priority under 35 U.S.C. § 119(a) to Japanese Patent Application No. 2021-159403 filed on Sep. 29, 2021 and Japanese Patent Application No. 2022-048322 filed on Mar. 24, 2022. The above applications are hereby expressly incorporated by reference, in their entirety, into the present application.

### BACKGROUND OF THE INVENTION

### 1. Field of the Invention

The present invention relates to an analysis method of a photosensitive composition, a production method of a photosensitive composition, and a manufacturing method of an electronic device.

### 2. Description of the Related Art

It has been known that a semiconductor device is manufactured by forming a fine electronic circuit pattern on a substrate using a photolithography technique.

Specifically, a pattern is obtained by forming a coating film (resist film) obtained using a photosensitive composition on a substrate, and then subjecting the coating film to various treatments such as an exposure treatment by light irradiation, a development treatment using a developer, and to a rinsing treatment using a rinsing liquid, as necessary. Using the pattern thus obtained as a mask, various treatments are performed to form an electronic circuit pattern.

In such a semiconductor device forming step, there is a demand for a pattern forming method capable of further suppressing occurrence of defects in order to further improve yield of the semiconductor device obtained. In recent years, manufacturing of a semiconductor device having a node of 10 nm or less has been studied, and this tendency has been more remarkable.

By the way, one of causes of the defects in a pattern may be foreign matters contained in the photosensitive composition.

For example, JP2000-005546A discloses a technique of removing foreign matters such as fine particles using a filter.

### SUMMARY OF THE INVENTION

As described above, a technique of removing foreign matters such as fine particles has been developed, and accordingly, a method capable of measuring the presence or absence of metal atoms at a more trace level has been required.

As a method of measuring metal atoms in the photosensitive composition, an inductively coupled plasma mass spectrometry (ICP-MS) is known.

However, in the above-described analysis method, it is not possible to evaluate the presence or absence of metal atoms in the photosensitive composition at a trace level required in recent years.

Therefore, an object of the present invention is to provide an analysis method of a photosensitive composition, with which a trace amount of metal atoms contained in the photosensitive composition can be easily detected.

Another object of the present invention is to provide a production method of a photosensitive composition and a manufacturing method of an electronic device using the analysis method.

The present inventors have found that the above-described objects can be achieved by the following configurations.

(1) An analysis method of a photosensitive composition, comprising:
a step 1 of applying a photosensitive composition onto a substrate to form a coating film;
a step 2 of removing the coating film from the substrate without exposing the coating film to obtain a coating film-removed substrate; and
a step 3 of measuring the number of metal atoms per unit area on the coating film-removed substrate by a total reflection X-ray fluorescence analysis method to obtain a measured value.

(2) The analysis method of a photosensitive composition according to (1), further comprising, between the step 2 and the step 3:
a step 4 of bringing a gas containing a hydrogen fluoride gas into contact with the coating film-removed substrate.

(3) The analysis method of a photosensitive composition according to (1) or (2), further comprising, between the step 2 and the step 3:
a step 5 of scanning the coating film-removed substrate with a solution containing hydrogen fluoride and hydrogen peroxide to collect metal atoms in the coating film-removed substrate in the solution.

(4) The analysis method of a photosensitive composition according to any one of (1) to (3),
in which, in the step 2, the coating film is removed using a solution.

(5) The analysis method of a photosensitive composition according to (4),
in which the solution is selected from the group consisting of an aqueous solution containing tetramethylammonium hydroxide, an ester-based organic solvent, an alcohol-based organic solvent, and a ketone-based organic solvent.

(6) The analysis method of a photosensitive composition according to (4) or (5),
in which the solution is selected from the group consisting of propylene glycol monomethyl ether acetate, propylene glycol monomethyl ether, methyl amyl ketone, cyclohexanone, ethyl lactate, butyl acetate, and γ-butyrolactone.

(7) The analysis method of a photosensitive composition according to any one of (4) to (6),
in which, in the step 2, a removal time of the coating film is 300 seconds or less.

(8) The analysis method of a photosensitive composition according to (7),
in which the removal time of the coating film is 180 seconds or less.

(9) The analysis method of a photosensitive composition according to any one of (1) to (3),
in which, in the step 2, the coating film is removed using a gas.

(10) The analysis method of a photosensitive composition according to (9),
in which the gas is selected from the group consisting of a fluorine-based gas, an oxygen-based gas, and a rare gas.

(11) The analysis method of a photosensitive composition according to (9) or (10),
in which, in the step 2, a removal time of the coating film is 300 seconds or less.

(12) The analysis method of a photosensitive composition according to (11),
in which a removal time of the coating film is 180 seconds or less.

(13) A production method of a photosensitive composition, comprising:
a step of preparing a photosensitive composition; and
a step of performing the analysis method according to any one of (1) to (12) on the prepared photosensitive composition.

(14) A manufacturing method of an electronic device, comprising:
a step of performing the analysis method according to any one of (1) to (12).

According to the present invention, it is possible to provide an analysis method of a photosensitive composition, with which a trace amount of metal atoms contained in the photosensitive composition can be easily detected.

In addition, according to the present invention, it is possible to provide a production method of a photosensitive composition and a manufacturing method of an electronic device using the analysis method.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

In notations for a group (atomic group) in the present specification, in a case where the group is cited without specifying that it is substituted or unsubstituted, the group includes both a group having no substituent and a group having a substituent as long as it does not impair the spirit of the present invention. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

A substituent is preferably a monovalent substituent unless otherwise specified.

“Light” in the present specification means actinic ray or radiation.

“Actinic ray” or “radiation” in the present specification means, for example, a bright line spectrum of a mercury lamp, far ultraviolet rays typified by an excimer laser, extreme ultraviolet rays (EUV light), X-rays, electron beams (EB), or the like.

Unless otherwise specified, “exposure” in the present specification encompasses not only exposure by a bright line spectrum of a mercury lamp, far ultraviolet rays typified by an excimer laser, extreme ultraviolet rays (EUV light), X-rays, or the like, but also drawing by particle beams such as electron beams and ion beams.

In the present specification, a numerical range expressed using “to” is used in a meaning of a range that includes the preceding and succeeding numerical values of “to” as the lower limit value and the upper limit value, respectively.

A bonding direction of a divalent group cited in the present specification is not limited unless otherwise specified. For example, in a case where Y in a compound represented by Formula “X—Y—Z” is —COO—, Y may be —CO—O— or —O—CO—. In addition, the above-described compound may be “X—CO—O—Z” or “X—O—CO—Z”.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, a weight-average molecular weight (Mw), a number-average molecular weight (Mn), and a dispersity (also referred to as a molecular weight distribution) (Mw/Mn) of a resin are defined as values expressed in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

In the present specification, examples of the halogen atom include a fluorine atom, a chlorine atom, a bromine atom, and an iodine atom.

In the present specification, a solid content means all components other than a solvent. Even in a case where the property of the solid content is liquid, the solid content is used for the calculation.

The analysis method of a photosensitive composition according to the embodiment of the present invention includes the following steps 1 to 3.
Step 1: step of applying (preferably, coating) a photosensitive composition onto a substrate to form a coating film
Step 2: step of removing the coating film from the substrate without exposing the coating film to obtain a coating film-removed substrate
Step 3: step of measuring the number of metal atoms per unit area on the coating film-removed substrate by a total reflection X-ray fluorescence analysis method to obtain a measured value

As a feature point of the above-described analysis method, the analysis of the metal atoms contained in the photosensitive composition by the total reflection X-ray fluorescence analysis method is performed on the substrate. Hereinafter, a mechanism of action thereof will be described.

In the step 1 of the above-described analysis method, the coating film is once formed on the substrate using the photosensitive composition, and in the subsequent step 2, a removal treatment of removing the coating film from the substrate is performed. As a result of the removal treatment, metal impurities including fine metal atoms, contained in the coating film, may adhere to the surface of the substrate which has passed through the step 2. In the step 3 of the analysis method according to the embodiment of the present invention, the metal atoms present on the surface of the substrate which has passed through the step 2 are measured by the total reflection X-ray fluorescence analysis method. That is, in the analysis method according to the embodiment of the present invention, the metal atoms contained in the photosensitive composition are analyzed on the substrate by the total reflection X-ray fluorescence analysis method.

Hereinafter, each step of the analysis method of a photosensitive composition according to the embodiment of the present invention will be described.

### <Step 1>

The step 1 is a step of applying (preferably, coating) a photosensitive composition onto a substrate to form a coating film.

Hereinafter, various materials used in the step 1 and a procedure of the step 1 will be described.

### (Photosensitive Composition)

The photosensitive composition used in the present step will be described later.

### (Substrate)

The type and size of the substrate is not particularly limited, and a known substrate used for manufacturing a semiconductor substrate is preferably used. Examples of the substrate include a glass substrate, a silicon substrate, and a sapphire substrate, and a silicon wafer is preferable.

In addition, the size of the substrate is, for example, approximately 300 mm in diameter, but it is not limited thereto.

It is preferable that the substrate used in the present step is washed in advance, and foreign matters and defects on the substrate are removed. The size of the foreign matters and the defects on the substrate is not particularly limited, but examples thereof include 20 nm or more.

### (Procedure of Step 1)

Examples of a method of forming a coating film on a substrate using a photosensitive composition include a method in which the photosensitive composition is applied onto the substrate. In addition, other examples of the coating method include a coating method using a coater cup and a coating method using an alkali development unit. In addition, a coating method using a spin coating method with a spinner is also preferable. A rotation speed upon the spin coating using a spinner is preferably 500 to 3000 rpm.

It is preferable that the substrate is dried after the photosensitive composition is applied onto the substrate.

Examples of the drying method include a method of heating and drying. The heating can be carried out using a unit included in an ordinary exposure machine and/or development machine, and may also be carried out using a hot plate or the like. A heating temperature is preferably 80° C. to 150° C., more preferably 80° C. to 140° C., and still more preferably 80° C. to 130° C. A heating time is preferably 30 to 1000 seconds, more preferably 60 to 800 seconds, and still more preferably 60 to 600 seconds. In one aspect, it is preferable to carry out heating at 90° C. for 90 seconds.

A film thickness of the coating film is not particularly limited, but is preferably 10 to 1000 nm and more preferably 10 to 120 nm. Among these, it is preferable to consider the film thickness for each use of the photosensitive composition, and for example, in a case where the photosensitive composition is subjected to pattern formation by EUV exposure or EB exposure, the film thickness of the coating film is still more preferably 10 to 100 nm. In addition, for example, in a case where the photosensitive composition is subjected to pattern formation by ArF liquid immersion exposure, the film thickness of the coating film is still more preferably 15 to 90 nm.

### <Step 2>

The step 2 is a step of removing the coating film from the substrate without exposing the coating film to obtain a coating film-removed substrate.

The expression “without exposing the coating film” as used herein means that an exposure treatment at an exposure amount equal to or more than a minimum exposure amount at which a residual film (a cured film after the coating film is exposed) is observed is not performed. That is, the exposure treatment of exposing the coating film to form a pattern is not performed in the step 2.

A method of removing the coating film in the step 2 is not particularly limited, and examples thereof include a method of removing the coating film using a solution and a method of removing the coating film using a gas.

Hereinafter, each of the methods will be described in detail.

The solution used in the method of removing the coating film using a solution is not particularly limited as long as the solution has a dissolving ability capable of removing the coating film. From the viewpoint of excellent removability of the coating film, examples of the above-described solution include an alkali developer (preferably an aqueous solution containing tetramethylammonium hydroxide) and an organic solvent.

Typical examples of the alkali developer include an alkali aqueous solution.

An alkali source of the alkali developer is not particularly limited, and examples thereof include inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcohol amines such as dimethylethanolamine and triethanolamine; tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide; quaternary ammonium salts such as trimethylphenylammonium hydroxide, trimethylbenzylammonium hydroxide, triethylbenzylammonium hydroxide, and dimethylbis(2-hydroxyethyl)ammonium hydroxide; and cyclic amines such as pyrrole and piperidine. Among these, the alkali source is preferably a quaternary ammonium salt, more preferably a tetraalkylammonium hydroxide (preferably having 1 to 6 carbon atoms in the alkyl moiety), and still more preferably tetramethylammonium hydroxide.

A content of the alkali source in the alkali aqueous solution is, for example, preferably 0.1% to 20% by mass, more preferably 0.1% to 5.0% by mass, and still more preferably 2.0% to 3.0% by mass with respect to the total mass of the alkali aqueous solution.

A pH of the alkali aqueous solution is, for example, preferably 10.0 to 15.0, more preferably 11.0 to 15.0, and still more preferably 12.0 to 15.0.

The alkali aqueous solution may contain alcohols and/or a surfactant.

As the alkali developer, an aqueous solution containing tetramethylammonium hydroxide is preferable.

Suitable ranges of a content of tetramethylammonium hydroxide and a pH of the aqueous solution are the same as the suitable ranges of the content of the alkali source in the alkali aqueous solution and the suitable range of the pH of the alkali aqueous solution described above.

The above-described pH is a value obtained by carrying out a measurement at a liquid temperature of 25° C. using a known pH meter.

The organic solvent is not particularly limited as long as it is an organic solvent capable of dissolving the coating film. Examples of the organic solvent include an ester-based organic solvent, an alcohol-based organic solvent, a ketone-based organic solvent, a hydrocarbon-based organic solvent, and an amide-based organic solvent. Among these, an ester-based organic solvent, an alcohol-based organic solvent, or a ketone-based organic solvent is preferable.

Examples of the ester-based organic solvent include propylene glycol monomethyl ether acetate, butyl acetate, ethyl lactate, γ-butyrolactone, methyl acetate, ethyl acetate, propyl acetate, methyl formate, ethyl formate, propyl formate, methyl pyruvate, ethyl pyruvate, propyl pyruvate, butyl pyruvate, methyl acetoacetate, and ethyl acetoacetate.

Examples of the alcohol-based organic solvent include propylene glycol monomethyl ether, methanol, ethanol, n-propanol, isopropanol (IPA), n-butanol, sec-butanol, t-butanol, n-pentanol, ethylene glycol, diethylene glycol, propylene glycol, and dipropylene glycol.

Examples of the ketone-based organic solvent include cyclohexanone, methyl amyl ketone, acetone, 1-hexanone, 2-hexanone, 1-octanone, and 2-octanone.

As the above-described solvent, propylene glycol monomethyl ether acetate, propylene glycol monomethyl ether, methyl amyl ketone, cyclohexanone, ethyl lactate, butyl acetate, or γ-butyrolactone is preferable.

The above-described solvent may be a mixed solvent. As the mixed solvent, a mixed solvent including two or more solvents selected from the group consisting of propylene glycol monomethyl ether acetate, propylene glycol monomethyl ether, methyl amyl ketone, cyclohexanone, ethyl lactate, butyl acetate, and γ-butyrolactone is preferable.

The method of removing the coating film using a solution is not particularly limited, and examples thereof include a method of bringing the coating film into contact with the solution. More specific examples thereof include a method of immersing the substrate having the coating film in a tank filled with the solution for a certain period of time, a method of spraying the solution onto the surface of the substrate, and a method of continuously jetting the solution while scanning a jetting nozzle at a constant rate on the substrate rotating at a constant rate.

In addition, as another example of the removal method, a removal method using a coater cup or a removal method using a spin coating method with a spinner is also preferable. A rotation speed in carrying out the removal method using a spin coating method with a spinner is preferably 500 to 3000 rpm. In addition, a supply flow rate of the solution is preferably 0.2 to 15 mL/s and more preferably 0.2 to 12 mL/s.

A temperature of the solution is not particularly limited, but is preferably 20° C. to 160° C. and more preferably 20° C. to 120° C.

A removal time of the coating film using the solution is preferably 800 seconds or less, more preferably 300 seconds or less, and still more preferably 180 seconds or less. The lower limit value thereof is often, for example, 5 seconds or more. In a case where the removal time in the step 2 is within the above-described range, the coating film is efficiently removed and the metal atoms on the substrate are hardly removed, so that more accurate measurement can be performed in the total reflection X-ray fluorescence analysis method in the step 3. More specifically, a variation in values in a case where the step 3 is performed a plurality of times is reduced.

From the viewpoint of being able to perform more accurate measurement in the total reflection X-ray fluorescence analysis method, one preferred aspect is an aspect in which the method of removing the coating film using the solution and a step 5 described later are combined.

After removing the coating film using the solution, a rinsing treatment may be performed as necessary.

In a case where the alkali developer is used in the step 2, it is preferable to use pure water as a rinsing liquid in the rinsing treatment. In addition, an appropriate amount of a surfactant may be added to the rinsing liquid.

In addition, as a reduction of the defect source (the number of defects), pure water after being filtered by a POU filter in an apparatus may be used.

In the rinsing treatment, in a case where the substrate after the removal of the coating film is subjected to a washing treatment using the above-described rinsing liquid containing pure water, a method for the washing treatment is not particularly limited, and for example, a method in which a rinsing liquid is continuously jetted on a substrate rotating at a constant rate (a spin coating method), a method in which a substrate is dipped in a tank filled with a rinsing liquid for a certain period of time (a dipping method), a method in which a rinsing liquid is sprayed on a substrate surface (a spray method), and the like, and among these, a method in which a washing treatment is performed using the rotation application method, and a substrate is rotated at a rotation speed of 2000 to 4000 rpm after washing, thereby removing the rinsing liquid from the substrate, is preferable. The rinsing according to the above-described method can be performed in an alkali development unit.

In addition, in a case where the organic solvent is used in the step 2, the rinsing treatment may be performed after the step 2, but from the viewpoint of throughput (productivity), amount of rinsing liquid used, and the like, the rinsing treatment may not be performed.

In a case where the organic solvent is used in the step 2, as the rinsing liquid, a solution containing a general organic solvent can be used. As the above-described rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, ketone-based solvent, ester-based solvent, alcohol-based solvent, amide-based solvent, and ether-based solvent described above include the same solvents as those described for the developer containing an organic solvent, which can be used in the step 2, and butyl acetate or methyl isobutyl carbinol is particularly preferable.

In a case where the organic solvent is used in the step 2, it is preferable to perform the rinsing treatment using a rinsing liquid containing at least one organic solvent selected from the group consisting of an ester-based solvent, an alcohol-based solvent, and a hydrocarbon-based solvent, and it is more preferable to perform the rinsing treatment using a rinsing liquid containing an alcohol-based solvent or a hydrocarbon-based solvent.

In a case where the organic solvent is used in the step 2, as the organic solvent contained in the rinsing liquid, a hydrocarbon-based solvent is preferable, and an aliphatic hydrocarbon-based solvent is more preferable. As the above-described aliphatic hydrocarbon-based solvent, from the viewpoint of further improving the effect, an aliphatic hydrocarbon-based solvent having 5 or more carbon atoms (for example, pentane, hexane, octane, decane, undecane, dodecane, hexadecane, and the like) is preferable, an aliphatic hydrocarbon-based solvent having 8 or more carbon atoms is more preferable, and an aliphatic hydrocarbon-based solvent having 10 or more carbon atoms is still more preferable.

The upper limit value of the number of carbon atoms in the above-described aliphatic hydrocarbon-based solvent is not particularly limited, but is preferably 16 or less, more preferably 14 or less, and still more preferably 12 or less.

Among the above-described aliphatic hydrocarbon-based solvents, decane, undecane, or dodecane is preferable, and undecane is more preferable.

A plurality of the above-described respective components may be mixed with each other, or may be mixed with an organic solvent other than the above-described organic solvents.

A moisture content in the rinsing liquid containing the organic solvent is preferably 10% by mass or less, more preferably 5% by mass or less, and still more preferably 3% by mass or less.

In a case where the organic solvent is used in the step 2, a vapor pressure of the rinsing liquid at 20° C. is preferably 0.05 to 5 kPa, more preferably 0.1 to 5 kPa, and still more preferably 0.12 to 3 kPa. By setting the vapor pressure of the rinsing liquid to 0.05 to 5 kPa, temperature uniformity in a wafer plane is improved.

An appropriate amount of a surfactant may be added to the rinsing liquid containing the organic solvent.

In a case where the washing treatment is performed using the rinsing liquid containing the organic solvent, a method for the washing treatment is not particularly limited, and for example, a method in which a rinsing liquid is continuously jetted on a substrate rotating at a constant rate (a spin coating method), a method in which a substrate is dipped in a tank filled with a rinsing liquid for a certain period of time (a dipping method), a method in which a rinsing liquid is sprayed on a substrate surface (a spray method), and the like, and among these, a method in which a washing treatment is performed using the rotation application method, and a substrate is rotated at a rotation speed of 2000 rpm to 4000 rpm after washing, thereby removing the rinsing liquid from the substrate, is preferable. In addition, it is also preferable that the method includes a heating step (post bake) after the rinsing step. A heating temperature in the heating step after the rinsing step is preferably 40° C. to 160° C. and more preferably 70° C. to 95° C., and a heating time is preferably 10 seconds to 3 minutes and more preferably 30 to 90 seconds.

In addition, a treatment of removing the solution used in the step 2 or the rinsing liquid with a supercritical fluid may be performed after the step 2 or the rinsing treatment.

It is preferable that the substrate is dried after performing the removal treatment.

Examples of the drying method include a method of heating and drying. The heating can be carried out using a unit included in an ordinary exposure machine and/or development machine, and may also be carried out using a hot plate or the like. A heating temperature is preferably 40° C. to 200° C., more preferably 70° C. to 160° C., and still more preferably 80° C. to 130° C. A heating time is preferably 30 to 1000 seconds, more preferably 30 to 800 seconds, still more preferably 30 to 600 seconds, and particularly preferably 30 to 200 seconds.

The gas used in the method of removing the coating film using a gas is not particularly limited as long as it has a performance of capable of removing the coating film. From the viewpoint of excellent removability of the coating film, examples of the above-described gas include a fluorine-based gas, an oxygen-based gas, and a rare gas.

Examples of the fluorine-based gas include a gas in which a hydrogen atom of a hydrocarbon is substituted with a fluorine atom, and CF₄ and CHF₃ are exemplified.

Examples of the oxygen-based gas include oxygen (O₂), carbon dioxide (CO₂), and nitrogen oxide gas (N₂O, NO, and NO₂)).

Examples of the rare gas include helium gas, neon gas, argon gas, krypton gas, and xenon gas.

The method of removing the coating film using a gas is not particularly limited, and examples thereof include a dry etching treatment. In the dry etching treatment, an introduced gas collides with electrons in plasma, and active radicals and reactive ions which are dissociated into various forms are generated to cause etching.

Conditions of the dry etching treatment are appropriately and optimally selected depending on the material of the coating film.

A removal time of the coating film using the gas is preferably 800 seconds or less, more preferably 300 seconds or less, and still more preferably 180 seconds or less. The lower limit value thereof is often, for example, 5 seconds or more. In a case where the removal time in the step 2 is within the above-described range, the coating film is efficiently removed and the metal atoms on the substrate are hardly removed, so that more accurate measurement can be performed in the total reflection X-ray fluorescence analysis method in the step 3. More specifically, a variation in values in a case where the step 3 is performed a plurality of times is reduced. From the viewpoint of being able to perform more accurate measurement in the total reflection X-ray fluorescence analysis method, one preferred aspect is an aspect in which the method of removing the coating film using the gas and a step 5 described later are combined.

### <Step 3>

The step 3 is a step of measuring the number of metal atoms per unit area on the coating film-removed substrate by a total reflection X-ray fluorescence analysis method to obtain a measured value.

The total reflection X-ray fluorescence analysis (TXRF) method is a technique in which excitation X-rays (primary X-rays) are applied to the surface of a sample at a very small incident angle so that the total reflection of the incident light from an excitation X-ray source occurs on the surface of the sample, and then, while X-rays totally reflected on the surface of the sample are released to the side of the sample, fluorescent X-rays (secondary X-rays) generated by being excited by impurities present on the surface of the sample are detected as the characteristic X-rays of the impurities by a fluorescent X-ray detector disposed to be opposite to the sample surface.

Measurement conditions of the TXRF method are not particularly limited and are appropriately adjusted.

A unit of the above-described measured value is atms/cm².

### <Step 4>

The analysis method of a photosensitive composition according to the embodiment of the present invention may further include, between the step 2 and the step 3, a step 4 of bringing a hydrogen fluoride gas into contact with the coating film-removed substrate.

In a case where the present analysis method includes the step 4, since a form of the metal impurities present on the coating film-removed substrate is uniform and an oxide film or the like on the coating film-removed substrate is removed, the measurement sensitivity by the TXRF method is further improved.

In general, examples of the form of the metal impurities containing the metal atoms, present on the coating film-removed substrate, include a form of particles or film adhered to the substrate and a form of being bonded to an atom constituting the substrate (for example, a silicide form in a case of a silicon substrate).

In a case where the present analysis method includes the step 4, by the step 4, the form of the metal impurities is easily uniformized, and an oxide film (SiO₂) or the like formed on the surface of the coating film-removed substrate is also removed.

A method of bringing the hydrogen fluoride gas into contact with the coating film-removed substrate is not particularly limited, and examples thereof include a method of holding the substrate in a hydrogen fluoride gas atmosphere. More specifically, a method described in paragraphs 0013 to 0015 of JP2001-153768A can be adopted.

### <Step 5>

The analysis method of a photosensitive composition according to the embodiment of the present invention may further include, between the step 2 and the step 3, a step 5 of scanning the coating film-removed substrate with a solution containing hydrogen fluoride and hydrogen peroxide to collect the metal atoms in the coating film-removed substrate in the solution.

By scanning the coating film-removed substrate with the above-described solution, an oxide film or the like on the coating film-removed substrate is removed, and the metal impurities containing the metal atoms on the coating film-removed substrate can be separated from the coating film-removed substrate and can be incorporated into the solution. A form in which the metal impurities are incorporated into the solution is not particularly limited, and examples thereof include dissolution, dispersion, and precipitation.

In a case where the oxide film on the coating film-removed substrate is removed by the scanning with the solution, a hydrophobic surface of the substrate is exposed, and the above-described solution easily moves on the coating film-removed substrate. As a result, the solution containing the metal impurities is more easily collected. A method for collecting is not particularly limited, and examples thereof include a method of gathering the above-described solution at one or more locations on the coating film-removed substrate and a method of gaining the solution from the coating film-removed substrate.

In a case where the gathered solution is dried, the metal impurities incorporated into the above-described solution precipitate on the coating film-removed substrate. In a case where a content of the precipitated metal impurities is analyzed by the above-described total reflection X-ray fluorescence analysis method, the amount and type of the metal atoms on the coating film-removed substrate can be analyzed. Even in a case where the solution is gained from the coating film-removed substrate, the solution may be coated on a new substrate in the same manner as described above, and the amount and type of metal impurities on the new substrate may be analyzed by the above-described method.

In the present specification, an operation of precipitating the metal impurities on the coating film-removed substrate by the above-described operation is also called concentration integration.

### <Photosensitive Composition>

The photosensitive composition in the analysis method according to the embodiment of the present invention is not particularly limited, and examples thereof include known photosensitive compositions.

Specific aspects of the photosensitive composition will be described in detail later, but in a case where the presence of the metal atoms is confirmed by the above-described analysis method of the photosensitive composition, the photosensitive composition often contains metal impurities including the metal atoms.

The type of the metal atom is not particularly limited, and examples thereof include at least one specific atom selected from the group consisting of Fe, Cr, Ti, Ni, and Al. The metal impurities may contain only one kind of the metal atom or may contain two or more kinds of the metal atoms.

A form of the metal impurities is not particularly limited as long as the metal impurities contain a metal atom. Examples thereof include a simple metal atom, a compound containing a metal atom (hereinafter, also referred to as “metal compound”), and a composite body thereof.

One suitable aspect of the photosensitive composition is a photosensitive composition containing an alkali-soluble component. Hereinafter, an example of an aspect of a photosensitive composition containing an alkali-soluble component, suitable as the photosensitive composition, will be described.

The photosensitive composition containing an alkali-soluble component means a photosensitive composition in which an exposed portion is cured and a non-exposed portion can be removed by an alkali developer.

As the photosensitive composition containing an alkali-soluble component, for example, a known negative tone photosensitive composition capable of being developed with alkali can be used. In the negative tone photosensitive composition capable of being developed with alkali, an exposed portion is usually cured and a non-exposed portion can be removed by an alkali developer.

In addition, the alkali-soluble component is preferably a component which can be dissolved (including both partial dissolution and complete dissolution) in an alkali developer used in pattern formation. Examples of a suitable aspect of the alkali-soluble component include an alkali-soluble resin having a phenolic hydroxyl group. The phenolic hydroxyl group is a group formed by substituting a hydrogen atom of an aromatic ring group with a hydroxy group. The aromatic ring in the above-described aromatic ring group may be a monocycle or a polycycle, and examples thereof include a benzene ring and a naphthalene ring.

Hereinafter, an example of an aspect of a negative tone photosensitive composition suitable as the photosensitive composition will be described.

### (Suitable Aspect 1 of Negative Tone Photosensitive Composition)

Examples of the negative tone photosensitive composition capable of being developed with alkali include a composition containing an alkali-soluble resin, a photoacid generator, a crosslinking agent, and a solvent.

Hereinafter, a specific form of a suitable aspect 1 of the negative tone photosensitive composition will be described with reference to a negative tone photosensitive composition (R) as an example.

The negative tone photosensitive composition (R) contains an alkali-soluble resin, a photoacid generator, a crosslinking agent, and a solvent.

### <<Alkali-Soluble Resin>>

As the alkali-soluble resin, an alkali-soluble resin having a phenolic hydroxyl group (hereinafter, also referred to as “resin (P)”) is preferable. The definition of the “phenolic hydroxyl group” is as described above.

### Repeating Unit Having Phenolic Hydroxyl Group

The resin (P) preferably includes a repeating unit having a phenolic hydroxyl group.

For example, the repeating unit having a phenolic hydroxyl group is preferably a repeating unit represented by General Formula (II).

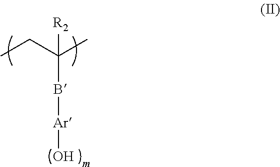

In the formula, R₂ represents a hydrogen atom, a methyl group which may have a substituent, or a halogen atom (preferably a fluorine atom). B′ represents a single bond or a divalent linking group. Ar′ represents an aromatic ring group. m represents an integer of 1 or more.

Examples of the methyl group which may have a substituent, represented by R₂, include a trifluoromethyl group and a hydroxymethyl group.

R₂ is preferably a hydrogen atom or a methyl group, and more preferably a hydrogen atom.

As the divalent linking group represented by B′, a carbonyl group, an alkylene group (preferably having 1 to 10 carbon atoms and more preferably having 1 to 5 carbon atoms), a sulfonyl group (—S(═O)₂—), —O—, —NH—, or a divalent linking group formed by a combination of these groups is preferable.

Among these, B′ is preferably a single bond, a carbonyloxy group (—C(═O)—O—), or —C(═O)—NH—, more preferably a single bond or a carbonyloxy group (—C(═O)—O—), and still more preferably a single bond.

The aromatic ring represented by Ar′ may be a monocycle or a polycycle, and examples thereof include aromatic hydrocarbon rings having 6 to 18 carbon atoms, which may have a substituent, such as a benzene ring, a naphthalene ring, an anthracene ring, a fluorene ring, and a phenanthrene ring; and aromatic heterocyclic rings including a hetero ring, such as a thiophene ring, a benzothiophene ring, a benzopyrrole ring, a triazine ring, an imidazole ring, a benzimidazole ring, a triazole ring, a thiadiazole ring, and a thiazole ring. Among these, an aromatic hydrocarbon ring is preferable, a benzene ring or a naphthalene ring is more preferable, and a benzene ring is still more preferable.

In addition, the aromatic ring represented by Ar′ may further have a substituent.

Examples of the substituent include an alkyl group, a cycloalkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

m is preferably an integer of 1 to 5, more preferably 1 or 3, and still more preferably 1.

In a case where m is 1 and Ar′ is a benzene ring, a substitution position of —OH may be any of a para-position, a meta-position, or an ortho-position with respect to a bonding position with B′ of the benzene ring (in a case where B′ is a single bond, to a polymer main chain), and the para-position is preferable.

The resin (P) may be a homopolymer composed of only the above-described repeating unit having a phenolic hydroxyl group, or may include other repeating units.

In a case where the resin (P) is a copolymer, a content of the repeating unit having a phenolic hydroxyl group is preferably 10% to 98% by mole, more preferably 30% to 97% by mole, and still more preferably 40% to 95% by mole with respect to all repeating units in the resin (P).

### Repeating Unit Including Group Having Non-Acid-Decomposable Hydrocarbon Structure

It is also preferable that the resin (P) includes a repeating unit (hereinafter also referred to as “non-acid-decomposable repeating unit”) including a group having a non-acid-decomposable hydrocarbon structure.

The non-acid-decomposable group means a property that a decomposition reaction does not occur by acid generated by the photoacid generator.

The group having a hydrocarbon structure is intended to be a group including at least one of a linear or branched hydrocarbon group or a cyclic (monocyclic or polycyclic) alicyclic hydrocarbon group, and may be bridged. In addition, in the above-described alicyclic hydrocarbon group, at least some of carbon atoms may be substituted with a heteroatom such as an oxygen atom and/or in carbonyl carbon (═CO).

Among these, the group having a hydrocarbon structure is preferably a cyclic (monocyclic or polycyclic) alicyclic hydrocarbon group.

Examples of the linear or branched hydrocarbon group include an alkyl group having 1 to 20 carbon atoms.

As the monocyclic alicyclic hydrocarbon group, a cycloalkyl group having 3 to 8 carbon atoms is preferable.

Examples of an alicyclic hydrocarbon which constitutes the polycyclic alicyclic hydrocarbon group include an alicyclic hydrocarbon having a bicyclo structure, a tricyclo structure, or a tetracyclo structure, each having 5 or more carbon atoms. Among these, the alicyclic hydrocarbon is preferably a polycyclic cycloalkane having 6 to 30 carbon atoms; more preferably an adamantane ring, a decalin ring, a norbornane ring, a norbornene ring, a cedrol ring, an isobornane ring, a bornane ring, a dicyclopentane ring, an α-pinene ring, a tricyclodecane ring, a tetracyclododecane ring, or an androstane ring; and still more preferably an adamantane ring.

In addition, the above-described group having a hydrocarbon structure may further have a substituent. Examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboxyl group, a carbonyl group, a thiocarbonyl group, an alkoxycarbonyl group (preferably having 2 to 7 carbon atoms), and a group formed by combining these groups (preferably having 1 to 30 total carbon atoms, and more preferably having 1 to 15 total carbon atoms).

Among these, the repeating unit including the group having a non-acid-decomposable hydrocarbon structure is preferably a repeating unit represented by General Formula (1).

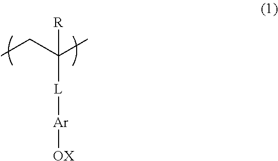

In the formula, R represents a hydrogen atom or a methyl group, X represents a group having a non-acid-decomposable hydrocarbon structure, Ar represents an aromatic ring, and L represents a single bond or a divalent linking group.

R is preferably a hydrogen atom.

Examples of the divalent linking group represented by L include a carbonyl group, an alkylene group (preferably having 1 to 10 carbon atoms and more preferably having 1 to 5 carbon atoms), a sulfonyl group (—S(═O)₂—), —O—, —NH—, and a divalent linking group formed by a combination of these groups.

L is preferably a single bond.

Examples of the aromatic ring represented by Ar include aromatic hydrocarbon rings having 6 to 18 carbon atoms, which may have a substituent, such as a benzene ring, a naphthalene ring, an anthracene ring, a fluorene ring, and a phenanthrene ring; and aromatic heterocyclic rings such as a thiophene ring, a benzothiophene ring, a benzopyrrole ring, a triazine ring, an imidazole ring, a benzimidazole ring, a triazole ring, a thiadiazole ring, and a thiazole ring. The aromatic ring represented by Ar is preferably a benzene ring or a naphthalene ring, and more preferably a benzene ring.

In addition, the aromatic ring represented by Ar may further have a substituent. Examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboxyl group, and an alkoxycarbonyl group (preferably having 2 to 7 carbon atoms).

As the group having a non-acid-decomposable hydrocarbon group, represented by X, a group represented by —Y—X₂ (Y represents a divalent linking group and X₂ represents the above-described group having a hydrocarbon structure) is preferable.

Examples of the divalent linking group represented by Y include a carbonyl group, a thiocarbonyl group, an alkylene group (preferably having 1 to 10 carbon atoms and more preferably having 1 to 5 carbon atoms), a sulfonyl group, —COCH₂—, —NH—, and a divalent linking group formed by a combination of these groups (preferably having 1 to 20 total carbon atoms and more preferably having 1 to 10 total carbon atoms), and a carbonyl group is preferable.

Examples of the group having a hydrocarbon structure, represented by X₂, include the above-described group having a hydrocarbon structure. Among these, the group having a hydrocarbon structure, represented by X₂, is preferably a cyclic (monocyclic or polycyclic) alicyclic hydrocarbon group, and more preferably an adamantane group.

A content of the repeating unit including a group having a non-acid-decomposable hydrocarbon structure is preferably 1% to 40% by mole and more preferably 2% to 30% by mole with respect to all repeating units of the resin (P).

### Other Repeating Units

The resin (P) may include other repeating units.

Examples of the other repeating units include each repeating unit described in paragraphs 0125 to 0237 of JP2015-148688A.

A weight-average molecular weight (Mw) of the resin (P) is preferably 1,000 to 200,000, more preferably 2,000 to 30,000, and still more preferably 3,000 to 25,000. A dispersity (Mw/Mn) is usually 1.0 to 3.0, preferably 1.0 to 2.6, more preferably 1.0 to 2.0, and still more preferably 1.1 to 2.0.

The resin (P) may be used alone or in combination of two or more kinds thereof.

A content of the resin (P) in the composition is preferably 20% to 99.5% by mass, more preferably 40% to 99% by mass, and still more preferably 55% to 98% by mass with respect to the total solid content.

### <<Crosslinking Agent>>

The crosslinking agent is a compound (including a resin) having a crosslinkable group capable of crosslinking a resin, and is preferably a compound which crosslinks the resin (P) by an action of acid.

As the crosslinking agent, known compounds can be appropriately used, and examples thereof include known compounds described in paragraphs [0379] to [0431] of US2016/0147154A1 and paragraphs [0064] to [0141] of US2016/0282720A1.

Examples of the crosslinkable group include a hydroxymethyl group, an alkoxymethyl group, an acyloxymethyl group, an alkoxymethyl ether group, an oxirane ring, and an oxetane ring, and a hydroxymethyl group, an alkoxymethyl group, an oxirane ring, or an oxetane ring is preferable.

The crosslinking agent is preferably a compound having two or more crosslinkable groups.

The crosslinking agent is preferably a phenol derivative, a urea-based compound (compound having a urea structure), or a melamine-based compound (compound having a melamine structure), which has a hydroxymethyl group or an alkoxymethyl group.

The crosslinking agent may be used alone or in combination of two or more kinds thereof.

A content of the crosslinking agent in the composition is preferably 1% to 50% by mass, more preferably 3% to 40% by mass, and still more preferably 5% to 30% by mass with respect to the total solid content of the composition.

### <<Photoacid Generator>>

The photoacid generator is a compound which generates an acid by irradiation with actinic ray or radiation.

Examples of the photoacid generator include a photoacid generator X and a photoacid generator Y The composition contains only the photoacid generator X, or contains both the photoacid generator X and the photoacid generator Y

### Photoacid Generator X

The photoacid generator X is preferably a compound which generates an organic acid by irradiation with actinic ray or radiation. Examples thereof include a sulfonium salt compound, an iodonium salt compound, a diazonium salt compound, a phosphonium salt compound, an imidosulfonate compound, an oxime sulfonate compound, a diazodisulfone compound, a disulfone compound, and an o-nitrobenzyl sulfonate compound.

As the photoacid generator X, a known compound which generates an acid by irradiation with actinic ray or radiation can be appropriately selected and used alone or as a mixture. For example, known compounds described in paragraphs [0125] to [0319] of US2016/0070167A1, paragraphs [0086] to [0094] of US2015/0004544A1, and paragraphs [0323] to [0402] of US2016/0237190A1 can be suitably used.

As the photoacid generator X, for example, a compound represented by General Formula (ZI), a compound represented by General Formula (ZII), or a compound represented by General Formula (ZIII) is preferable.

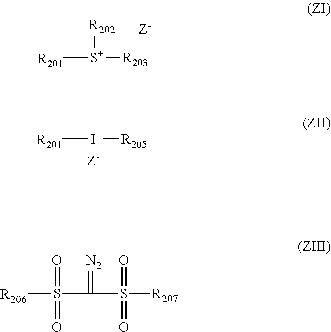

In General Formula (ZI),

R₂₀₁, R₂₀₂, and R₂₀₃ each independently represent an organic group.

The organic group as R₂₀₁, R₂₀₂, and R₂₀₃ generally has 1 to 30 carbon atoms, preferably has 1 to 20 carbon atoms.

In addition, two of R₂₀₁ to R₂₀₃ may be bonded to each other to form a ring structure, and the ring structure may include an oxygen atom, a sulfur atom, an ester bond, an amide bond, or a carbonyl group in the ring. Examples of the group formed by the bonding of two of R₂₀₁ to R₂₀₃ include an alkylene group (for example, a butylene group and a pentylene group) and —CH₂—CH₂—O—CH₂—CH₂—.

Z⁻ represents an anion (preferably a non-nucleophilic anion).

Next, General Formulae (ZII) and (ZIII) will be described.

In General Formulae (ZII) and (ZIII), R₂₀₄ to R₂₀₇ each independently represent an aryl group, an alkyl group, or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group which has a heterocyclic structure having an oxygen atom, a nitrogen atom, a sulfur atom, or the like. Examples of a skeleton of the aryl group having a heterocyclic structure include pyrrole, furan, thiophene, indole, benzofuran, and benzothiophene.

The alkyl group and cycloalkyl group of R₂₀₄ to R₂₀₇ are preferably a linear alkyl group having 1 to 10 carbon atoms or a branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, and a norbornyl group).

The aryl group, the alkyl group, and the cycloalkyl group of R₂₀₄ to R₂₀₇ may each independently have a substituent. Examples of the substituent which may be included in the aryl group, the alkyl group, and the cycloalkyl group of R₂₀₄ to R₂₀₇ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z⁻ represents an anion.

As Z⁻ in General Formula (ZI) and Z⁻ in General Formula (ZII), an anion represented by General Formula (3) is preferable.

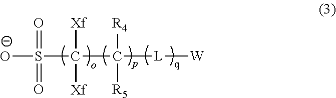

In General Formula (3),

o represents an integer of 1 to 3, p represents an integer of 0 to 10, and q represents an integer of 0 to 10.

Xf represents a fluorine atom or an alkyl group substituted with at least one fluorine atom. The number of carbon atoms in the alkyl group is preferably 1 to 10 and more preferably 1 to 4. In addition, the alkyl group substituted with at least one fluorine atom is preferably a perfluoroalkyl group.

Xf is preferably a fluorine atom or a perfluoroalkyl group having 1 to 4 carbon atoms, and more preferably a fluorine atom or CF₃. In particular, it is still more preferable that both Xf's are fluorine atoms.

R₄ and R₅ each independently represent a hydrogen atom, a fluorine atom, an alkyl group, or an alkyl group substituted with at least one fluorine atom. In a case of a plurality of R₄'s and R₅'s, R₄'s and R₅'s may be the same or different from each other.

The alkyl group represented by R₄ and R₅ may have a substituent, and preferably has 1 to 4 carbon atoms. R₄ and R₅ are preferably a hydrogen atom.

Specific examples and suitable aspects of the alkyl group substituted with at least one fluorine atom are the same as the specific examples and suitable aspects of Xf in General Formula (3).

L represents a divalent linking group. In a case of a plurality of L's, L's may be the same or different from each other.

Examples of the divalent linking group include —COO—, —CONH—, —CO—, —O—, —S—, —SO—, —SO₂—, an alkylene group (preferably having 1 to 6 carbon atoms), a cycloalkylene group (preferably having 3 to 15 carbon atoms), an alkenylene group (preferably having 2 to 6 carbon atoms), and a divalent linking group formed by a combination of a plurality of these groups. Among these, —COO—, —CONH—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

W represents an organic group including a cyclic structure. Among these, a cyclic organic group is preferable.

Examples of the cyclic organic group include an alicyclic group, an aryl group, and a heterocyclic group.

The alicyclic group may be monocyclic or polycyclic. Examples of the monocyclic alicyclic group include a monocyclic cycloalkyl group such as a cyclopentyl group, a cyclohexyl group, and a cyclooctyl group. Examples of the polycyclic alicyclic group include a polycyclic cycloalkyl group such as a norbornyl group, a tricyclodecanyl group, a tetracyclodecanyl group, a tetracyclododecanyl group, and an adamantyl group. Among these, an alicyclic group having a bulky structure with 7 or more carbon atoms, such as a norbornyl group, a tricyclodecanyl group, a tetracyclodecanyl group, a tetracyclododecanyl group, and an adamantyl group, is preferable.

The aryl group may be monocyclic or polycyclic. Examples of the aryl group include a phenyl group, a naphthyl group, a phenanthryl group, and an anthryl group.

The heterocyclic group may be monocyclic or polycyclic. A polycyclic heterocyclic group can further suppress acid diffusion. In addition, the heterocyclic group may or may not have aromaticity. Examples of a heterocycle having aromaticity include a furan ring, a thiophene ring, a benzofuran ring, a benzothiophene ring, a dibenzofuran ring, a dibenzothiophene ring, and a pyridine ring. Examples of a heterocycle not having aromaticity include a tetrahydropyran ring, a lactone ring, a sultone ring, and a decahydroisoquinoline ring. Examples of the lactone ring and the sultone ring include the lactone structures and sultone structures exemplified in the above-described resin. As the heterocycle in the heterocyclic group, a furan ring, a thiophene ring, a pyridine ring, or a decahydroisoquinoline ring is particularly preferable.

The above-described cyclic organic group may have a substituent. Examples of the substituent include an alkyl group (may be linear or branched; preferably having 1 to 12 carbon atoms), a cycloalkyl group (may be monocyclic, polycyclic, or spirocyclic; preferably having 3 to 20 carbon atoms), an aryl group (preferably having 6 to 14 carbon atoms), a hydroxyl group, an alkoxy group, an ester group, an amide group, a urethane group, a ureido group, a thioether group, a sulfonamide group, and a sulfonic acid ester group. A carbon constituting the cyclic organic group (carbon contributing to ring formation) may be a carbonyl carbon.

As the anion represented by General Formula (3), SO₃—CF₂—CH₂—OCO-(L)q′-W, SO₃⁻—CF₂—CHF—CH₂—OCO-(L)q′-W, SO₃—CF₂—COO-(L)q′-W, SO₃⁻—CF₂—CF₂—CH₂—CH₂-(L)q-W, or SO₃⁻—CF₂—CH(CF₃)—OCO-(L)q′-W is preferable. Here, L, q, and W are the same as in General Formula (3). q′ represents an integer of 0 to 10.

Z⁻ in General Formula (ZI) and Z⁻ in General Formula (ZII) may be a benzenesulfonate anion, and are preferably a benzenesulfonate anion substituted with a branched alkyl group or a cycloalkyl group.

As the photoacid generator X, for example, photoacid generators described in paragraphs [0135] to [0171] of WO2018/193954A, paragraphs [0077] to [0116] of WO2020/066824A, and paragraphs [0018] to [0075] and [0334] and [0335] of WO2017/154345A can be referred to. The contents thereof are incorporated in the present specification.

The photoacid generator X may be in a form of a low-molecular-weight compound or a form incorporated into a part of a polymer. In addition, a combination of the form of a low-molecular-weight compound and the form incorporated into a part of a polymer may also be used.

The photoacid generator X is preferably the form of a low-molecular-weight compound.

In a case where the photoacid generator X is in the form of a low-molecular-weight compound, the molecular weight is preferably 3,000 or less, more preferably 2,000 or less, and still more preferably 1,000 or less.

In a case where the photoacid generator X is in the form incorporated into a part of a polymer, it may be incorporated into the above-mentioned resin (P) or into a resin other than the resin (P).

The photoacid generators X may be used alone or in combination of two or more kinds thereof.

A content of the photoacid generator X (in a case where a plurality of the photoacid generators X are present, a total content thereof) in the composition is preferably 0.1% to 35% by mass, more preferably 0.5% to 25% by mass, still more preferably 1% to 20% by mass, and particularly preferably 1% to 15% by mass based on the total solid content of the composition.

### Photoacid Generator Y

The photoacid generator Y is a photoacid generator having an onium salt structure which is a relatively weak acid with respect to the photoacid generator X.

In a case of being used by mixing the photoacid generator X and the onium salt that generates an acid which is relatively weak with respect to the acid generated from the photoacid generator X, the acid generated from the photoacid generator X due to the irradiation with actinic ray or radiation collides with an onium salt having an unreacted weak-acid anion, so that salt exchange releases the weak acid to yield an onium salt with a strong-acid anion. In this process, since the strong acid is exchanged for the weak acid having a lower catalytic activity, the acid is apparently inactivated and the acid diffusion can be controlled.

As the photoacid generator Y, a compound represented by General Formulae (d1-1) to (d1-3) is preferable.

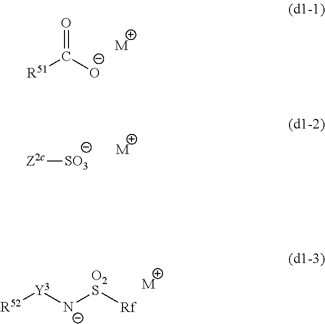

In the formulae, R⁵¹ is a hydrocarbon group which may have a substituent, Z^{2c} is a hydrocarbon group having 1 to 30 carbon atoms, which may have a substituent (provided that a carbon adjacent to S is not substituted with a fluorine atom), R⁵² is an organic group, Y³ is a linear, branched, or cyclic alkylene group or an arylene group, Rf is a hydrocarbon group including a fluorine atom, and M⁺'s are each independently an ammonium cation, a sulfonium cation, or an iodonium cation.

Preferred examples of the sulfonium cation or iodonium cation represented by M⁺ include the sulfonium cation exemplified in General Formula (ZI) and the iodonium cation exemplified in General Formula (ZII).

The onium salt (DC) which is a relatively weak acid with respect to the photoacid generator may be a compound having a cationic moiety and an anionic moiety in the same molecule, in which the cationic moiety and the anionic moiety are linked by a covalent bond (hereinafter, also referred to as “compound (DCA)”).

As the compound (DCA), a compound represented by any of General Formulae (C-1) to (C-3) is preferable.

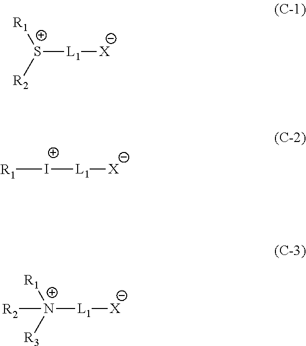

In General Formulae (C-1) to (C-3),

R₁, R₂, and R₃ each independently represent a substituent having 1 or more carbon atoms,

L₁ represents a divalent linking group or a single bond, which links the cationic moiety and the anionic moiety,

—X⁻ represents an anionic moiety selected from —COO⁻, —SO₃⁻, —SO₂⁻, or —N⁻R₄, R₄ represents a monovalent substituent having at least one of a carbonyl group (—C(═O)—), a sulfonyl group (—S(═O)₂—), or a sulfinyl group (—S(═O)—) at a linking site with an adjacent N atom, and R₁, R₂, R₃, R₄, and L₁ may be bonded to each other to form a ring structure. In addition, in General Formula (C-3), two of R₁ to R₃ together represent one divalent substituent, which may be bonded to an N atom by a double bond.

Examples of the substituent having 1 or more carbon atoms in R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group. An alkyl group, a cycloalkyl group, or an aryl group is preferable.

Examples of L₁ as the divalent linking group include a linear or branched alkylene group, a cycloalkylene group, an arylene group, a carbonyl group, an ether bond, an ester bond, an amide bond, a urethane bond, a urea bond, and a group formed by combining two or more thereof. L₁ is preferably an alkylene group, an arylene group, an ether bond, an ester bond, or a group formed by combining two or more thereof.

A content of the photoacid generator Y (in a case where a plurality of the photoacid generators Y are present, a total content thereof) in the composition is preferably 1.0×10⁻⁴% by mass or less, and more preferably 1.0×10⁻⁵% by mass or less with respect to the total solid content of the composition.

### <<Basic Compound>>

A basic compound functions as an acid diffusion control agent. Specifically, the basic compound acts as a quencher which suppresses a reaction of the acid-decomposable resin in the non-exposed portion by excessive generated acids by trapping the acids generated from the photoacid generator and the like during exposure.

Examples of the acid diffusion control agent include a basic compound (CA), a basic compound (CB) in which basicity decreases or disappears by irradiation with actinic ray or radiation, a low-molecular-weight compound (CD) which has a nitrogen atom and has a group eliminated by action of acid, and an onium salt compound (CE) which has a nitrogen atom in a cationic moiety.

As the basic compound, a known acid diffusion control agent can be appropriately used. For example, as the acid diffusion control agent, known compounds described in paragraphs [0627] to [0664] of US2016/0070167A1, paragraphs [0095] to [0187] of US2015/0004544A1, paragraphs [0403] to [0423] of US2016/0237190A1, and paragraphs [0259] to [0328] of US2016/0274458A1 can be suitably used.

In addition, specific examples of the basic compound (CA) include compounds described in paragraphs [0132] to [0136] of WO2020/066824A; specific examples of the basic compound (CB) in which basicity decreases or disappears in a case of being irradiated with actinic ray or radiation include compounds described in paragraphs [0137] to [0155] of WO2020/066824A; specific examples of the low-molecular-weight compound (CD) having a nitrogen atom and a group which is eliminated by action of acid include paragraphs [0156] to [0163] of WO2020/066824A; and specific examples of the onium salt compound (CE) having a nitrogen atom in the cationic moiety include paragraph [0164] of WO2020/066824A. The contents thereof are incorporated in the present specification.

As one aspect of the basic compound, the compound (CE) is preferable, and a compound having a basic site including a nitrogen atom in the cationic moiety is more preferable. The basic site is preferably an amino group and more preferably an aliphatic amino group. It is still more preferable that all of atoms adjacent to the nitrogen atom in the basic site are hydrogen atoms or carbon atoms. In addition, from the viewpoint of improving basicity, it is preferable that an electron-withdrawing functional group (a carbonyl group, a sulfonyl group, a cyano group, a halogen atom, or the like) is not directly connected to the nitrogen atom.

Preferred specific examples of the compound (CE) include compounds described in paragraph [0203] of US2015/0309408A1, but the compound (CE) is not limited thereto.

Preferred examples of the basic compound are shown below, but the present invention is not limited thereto.

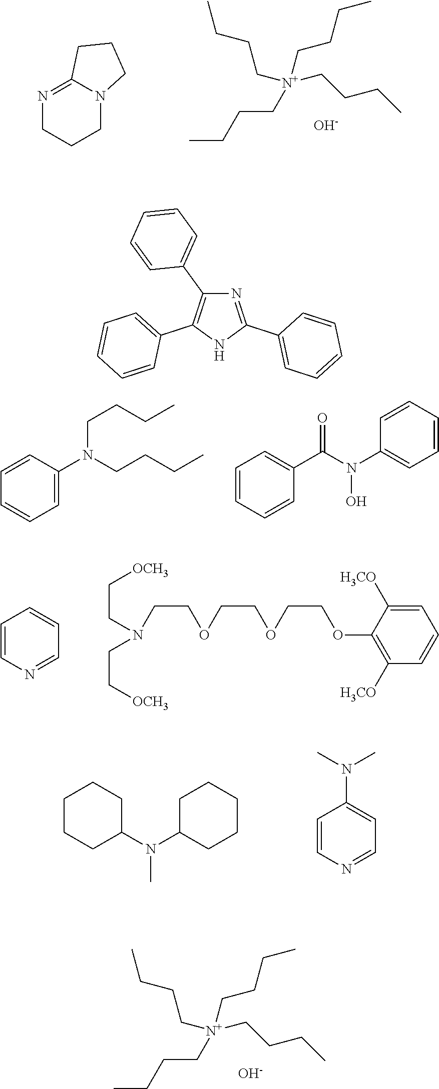

The basic compound may be used alone or in combination of two or more kinds thereof.

A content of the basic compound (in a case where a plurality of the basic compounds are present, a total content thereof) in the composition is preferably 0.001% to 20% by mass, and more preferably 0.01% to 10% by mass with respect to the total solid content of the composition.

### <<Solvent>>

As the solvent, a known resist solvent can be appropriately used. For example, known solvents described in paragraphs [0665] to [0670] of US2016/0070167A1, paragraphs [0210] to [0235] of US2015/0004544A1, paragraphs [0424] to [0426] of US2016/0237190A1, and paragraphs [0357] to [0366] of US2016/0274458A1 can be suitably used.

Examples of the solvent which can be used in preparation of the composition include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

As the organic solvent, a mixed solvent obtained by mixing a solvent having a hydroxyl group in the structure and a solvent having no hydroxyl group may be used.

The solvent having a hydroxyl group and the solvent having no hydroxyl group can be appropriately selected, but as the solvent having a hydroxyl group, alkylene glycol monoalkyl ether or alkyl lactate is preferable, and propylene glycol monomethyl ether (PGME: 1-methoxy-2-propanol), propylene glycol monoethyl ether (PGEE), methyl 2-hydroxyisobutyrate, or ethyl lactate (EL) is more preferable. In addition, as the solvent having no hydroxyl group, alkylene glycol monoalkyl ether acetate, alkyl alkoxypropionate, a monoketone compound which may have a ring, a cyclic lactone, alkyl acetate, or the like is preferable; and among these, propylene glycol monomethyl ether acetate (PGMEA: 1-methoxy-2-acetoxypropane), ethyl ethoxypropionate, 2-heptanone, γ-butyrolactone, cyclohexanone, cyclopentanone, or butyl acetate is more preferable, and propylene glycol monomethyl ether acetate, γ-butyrolactone, ethyl ethoxypropionate, cyclohexanone, cyclopentanone, or 2-heptanone is still more preferable. As the solvent having no hydroxyl group, propylene carbonate is also preferable.

A mixing ratio (mass ratio) of the solvent having a hydroxyl group and the solvent having no hydroxyl group is preferably 1/99 to 99/1, more preferably 10/90 to 90/10, and still more preferably 20/80 to 60/40. A mixed solvent containing 50% by mass or more of the solvent having no hydroxyl group is preferable from the viewpoint of coating uniformity.

The solvent preferably includes propylene glycol monomethyl ether acetate, and may be a single solvent of propylene glycol monomethyl ether acetate or a mixed solvent of two or more kinds including propylene glycol monomethyl ether acetate.

### <<Other Additives>>

The composition of the present invention may appropriately contain, in addition to the components described above, a surfactant, a carboxylic acid, an onium carboxylate salt, a dissolution inhibiting compound having a molecular weight of 3,000 or less described in Proceeding of SPIE, 2724,355 (1996) and the like, a dye, a plasticizer, a photosensitizer, a light absorbing agent, an antioxidant, and the like.

The carboxylic acid can be suitably used for improving performance. The carboxylic acid is preferably an aromatic carboxylic acid such as benzoic acid and naphthoic acid.

In a case where the composition contains a carboxylic acid, a content of the carboxylic acid is preferably 0.01% to 10% by mass, more preferably 0.01% to 5% by mass, and still more preferably 0.01% to 3% by mass with respect to the total solid content of the composition.

The surfactant is preferably a fluorine-based and/or silicon-based surfactant.

These surfactants may be used alone or in combination of two or more kinds thereof.

In a case where the composition contains a surfactant, a content of the surfactant is preferably 0% to 2% by mass, more preferably 0.0001% to 2% by mass, and still more preferably 0.0005% to 1% by mass with respect to the total solid content of the composition.

A concentration of solid contents in the composition is preferably 1.0% to 10% by mass, more preferably 2.0% to 5.7% by mass, and still more preferably 2.0% to 5.3% by mass.

### (Suitable Aspect 2 of Negative Tone Photosensitive Composition)

Another example of the negative tone photosensitive composition capable of being developed with alkali includes a composition containing a polymerizable compound, a photopolymerization initiator, and a solvent. In the composition, the polymerizable compound is preferably an alkali-soluble component.

In addition, it is also preferable that the composition contains a resin. The resin is preferably an alkali-soluble resin. The alkali-soluble resin can also be used as a dispersant or a binder. In a case where the composition contains an alkali-soluble resin, a content of the resin is preferably 0.1% to 40% by mass with respect to the total solid content of the composition.

In addition, in a case where the polymerizable compound includes a cyclic ether group, a methylol group, or an alkoxymethyl group, it is also preferable that the composition further includes a curing agent.

In addition, the composition may contain components such as a colorant (pigment or the like), a surfactant, a polymerization inhibitor, a silane coupling agent, an ultraviolet absorber, and an antioxidant.

Examples of the polymerizable compound include a compound (polymerizable compound) having a polymerizable group. Examples of the polymerizable group include an ethylenically unsaturated bond-containing group, a cyclic ether group, a methylol group, and an alkoxymethyl group. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Examples of the cyclic ether group include an epoxy group and an oxetanyl group.

The polymerizable compound may be a monomer or a polymer.

In a case where the polymerizable compound is a monomer, the number of polymerizable groups in the molecule is not particularly limited as long as it is 1 or more, and it is preferably 2 or more and more preferably 3 or more. The upper limit value thereof is not particularly limited, but is preferably 15 or less and more preferably 6 or less.

In a case where the polymerizable compound is a polymer, a polymer having a repeating unit having a polymerizable group is preferable.

In a case where the polymerizable compound is a monomer, a molecular weight of the polymerizable compound is preferably less than 2,000 and more preferably 1,500 or less. The lower limit thereof is preferably 100 or more and more preferably 200 or more.

In a case where the polymerizable compound is a polymer, a weight-average molecular weight (Mw) of the polymerizable compound is preferably 2,000 to 2,000,000. The upper limit value thereof is preferably 1,000,000 or less, more preferably 500,000, and still more preferably 100,000 or less. The lower limit value thereof is preferably 3,000 or more and more preferably 5,000 or more.

The polymerizable compound may be used alone or in combination of two or more kinds thereof.

A content of the polymerizable compound is preferably 1% to 95% by mass with respect to the total solid content of the composition.

Examples of the solvent include water and an organic solvent.

Examples of the organic solvent include propylene glycol monomethyl ether and propylene glycol monomethyl ether acetate.

The solvent may be used alone or in combination of two or more kinds thereof.

A content of the solvent in the composition is preferably 10% to 97% by mass with respect to the total mass of the composition.

The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

The photopolymerization initiator may be used alone or in combination of two or more kinds thereof.

A content of the photopolymerization initiator is preferably 0.1% to 40% by mass with respect to the total solid content of the composition.

In a case where the composition contains the compound having a cyclic ether group, the composition preferably further contains a curing agent. Examples of the curing agent include an amine compound, an acid anhydride compound, an amide compound, a phenol compound, polyvalent carboxylic acid, and a thiol compound. In a case where the curing agent is used, a content of the curing agent is preferably 0.01 to 20 parts by mass with respect to 100 parts by mass of the compound having a cyclic ether group.

Examples of the above-described negative tone photosensitive composition capable of being developed with alkali include a curable composition which can be used for forming various cured films in a manufacturing process of a solid-state imaging element (for example, a curable composition for forming a light shielding film or a color filter). Examples of such a curable composition include compositions described in JP2020-126253A and JP2020-073989A.

In the above, the negative tone photosensitive composition has been mainly described, but the present invention can also be adopted to the analysis of a positive tone photosensitive composition.

A configuration of the positive tone photosensitive composition is not particularly limited, and a known composition can be used. Examples of the positive tone photosensitive composition include an acid-decomposable resin having a group which is decomposed by the action of acid to generate a polar group, and a photosensitive composition containing a photoacid generator.

The above-described photosensitive composition may further contain other materials (for example, an acid diffusion control agent, a hydrophobic resin, a solvent, and the like).

### <Production Method of Photosensitive Composition>

The production method of a photosensitive composition according to the embodiment of the present invention includes the following composition preparation step and analysis step.

Composition preparation step: step of preparing a photosensitive composition

Analysis step: step of performing analysis based on the analysis method according to the embodiment of the present invention on the photosensitive composition obtained by the composition preparation step

The method of preparing the photosensitive composition and the analysis method are as described above, and suitable aspects thereof are also the same.

In a case where it is detected by the above-described analysis that the number of metal atoms derived from the photosensitive composition obtained through the composition preparation step is larger than a desired value, it is preferable to further perform a purification treatment on the photosensitive composition which has passed through the analysis. In addition, the analysis method according to the embodiment of the present invention may be performed only one time or a plurality of times after the adjustment of the photosensitive composition.

Examples of a suitable aspect of the production method according to the embodiment of the present invention include a production method including the following composition preparation step, analysis step, purification step, and re-analysis step. The above-described production method may further include a repeating step (one or more times for the repeating step) as necessary.

Composition preparation step: step of preparing a photosensitive composition

Analysis step: step of performing analysis based on the analysis method according to the embodiment of the present invention on the photosensitive composition obtained by the composition preparation step

Purification step: step of further subjecting the photosensitive composition which has passed through the analysis step to a purification treatment (for example, a filtration treatment)

Re-analysis step: step of performing analysis on the photosensitive composition which has passed through the purification step again based on the analysis method according to the embodiment of the present invention

Repeating step: step of performing the above-described purification step and re-analysis step again, in a case where the number of metal atoms derived from the photosensitive composition, which has been detected in the above-described re-analysis step, does not satisfy a predetermined value

### <Manufacturing Method of Electronic Device>

In addition, the present invention also relates to a manufacturing method of an electronic device, including a step of performing analysis based on the above-described analysis method according to the embodiment of the present invention, and to an electronic device manufactured by this manufacturing method.

As a specific aspect of the manufacturing method of an electronic device, it is preferable to include a step based on the above-described production method of a composition according to the embodiment of the present invention.

The electronic device is not particularly limited, and is, for example, suitably mounted on electric and electronic apparatus (for example, home appliances, office automation (OA)-related equipment, media-related equipment, optical equipment, telecommunication equipment, and the like).

### EXAMPLES

Hereinafter, the present invention will be described in more detail with reference to Examples. The materials, the amounts of materials used, the proportions, the treatment details, and the treatment procedure in Examples below may be appropriately modified as long as the modifications do not depart from the spirit of the present invention. Therefore, the scope of the present invention should not be construed as being limited to Examples described below.

In the following, among coating films formed on the substrate, a coating film after an exposure treatment may be described as “cured film of the coating film” or “residual film”, which are synonymous with each other.

### <Preparation of Photosensitive Compositions of Examples and Comparative Examples>

### (Preparation of Photosensitive Compositions A-1 and A-1A: Negative Tone Photosensitive Composition)

As a negative tone photosensitive composition, photosensitive compositions A-1 and A-1A were prepared by the following procedures. The abbreviations for solvents are as follows.
EL: Ethyl lactate
PGME: propylene glycol monomethyl ether
PGMEA: propylene glycol monomethyl ether acetate

### (Preparation of Photosensitive Composition A-1)

A photosensitive composition A-1 was prepared
by mixing the following components.

| | | |
|---|---|---|
| Resin P-8 shown below | 57.7 | parts by mass |
| Photoacid generator A-12 shown below | 8.1 | parts by mass |
| Photoacid generator B-1 shown below | 5.0 | parts by mass |
| Basic compound Q-1 shown below | 1.0 | part by mass |
| Crosslinking agent X-1 shown below | 28.2 | parts by mass |

Solvent (mixed solvent consisting of
EL/PGME/PGMEA (mass ratio: 60/20/20)
amount at which concentration of solid
contents was 2.6% by mass

### (Preparation of Photosensitive Composition A-1A)

A photosensitive composition A-1A was prepared
by mixing the following components.

| | | |
|---|---|---|
| Resin P-8 shown below | 57.7 | parts by mass |
| Photoacid generator A-12 shown below | 8.1 | parts by mass |
| Photoacid generator B-1 shown below | 5.0 | parts by mass |
| Basic compound Q-1 shown below | 1.0 | part by mass |
| Crosslinking agent X-1 shown below | 28.2 | parts by mass |

Solvent (mixed solvent consisting of
EL/PGME/PGMEA (mass ratio: 60/20/20))
amount at which concentration of solid
contents was 2.6% by mass
Iron stearate (III)
amount of iron that was 10 ppb by mass
with respect to the total mass of the
photosensitive composition

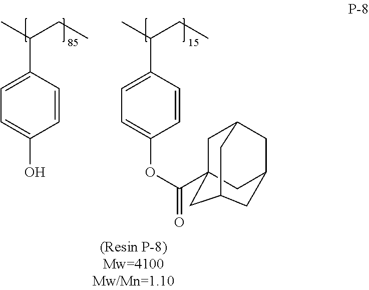

The numerical value shown for each repeating unit in the resin P-8 means a molar ratio.

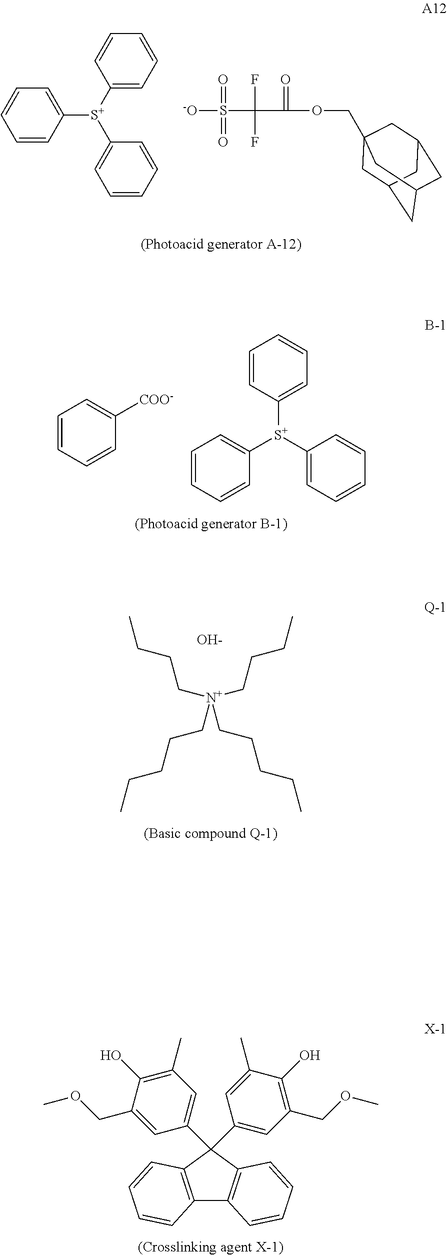

### (Filtration of Photosensitive Composition)

In addition, the photosensitive compositions A-1 and A-1A prepared by the above-described procedures were subjected to the following purification treatment, and the purified compositions were used in each of Examples.

Specifically, the photosensitive compositions A-1 and A-1A (both 12000 g) were each filtered through the following two-stage filter.

First stage: Nylon filter with a pore size of 5 nm, manufactured by PALL Corporation

Second stage: Polyethylene filter with a pore size of 1 nm, manufactured by Entegris

### Example 1: Formation of Coating Film (without Exposure)

The photosensitive composition A-1A was connected to a line of a resist of a coater of Clean Track ACT8 manufactured by Tokyo Electron Limited. During the connection, the filter was not connected to a connection pipe, and a dummy capsule was used.

Subsequently, the photosensitive composition connected by the above-described method was applied onto a 8-inch (diameter: 200 mm) silicon wafer with a coater, and then baked at 90° C. for 90 seconds to form a coating film (resist film). A film thickness of the coating film at this time was adjusted to 80 nm. As described above, an exposure treatment was not performed in the above-described step. In addition, the substrate on which the coating film had been formed was stored in a wafer case in a clean room until the coating film was provided for the subsequent removal.

Next, using an alkali developer (removal liquid), the coating film was removed from the silicon wafer with a coating film, obtained by performing the procedure of <Formation of coating film (without exposure)> described above.

The removal liquid used herein was an alkali developer X-W1 described in (Preparation of alkali developer (removal liquid used in step 2)) below.

### (Preparation of Alkali Developer (Removal Liquid Used in Step 2))

As an alkali developer, an alkali developer X shown below was prepared.

Alkali developer X: aqueous solution containing 2.38% by mass of tetramethylammonium hydroxide (TMAH)

Next, the alkali developer X was subjected to a point of use (POU) filter filtration in a coater under the conditions shown below to obtain an alkali developer X-W1, which was used in Examples. The “POU filter” corresponds to a filtration filter incorporated in the apparatus and used for purification immediately before use, and a polyethylene filter with a pore size of 10 nm, manufactured by Entegris, was used.

The coating film was removed using Clean TrackACT8 manufactured by Tokyo Electron Limited, to which the removal liquid before the filtration was connected. In the connection, the above-described POU filter was connected to the connection pipe and used. That is, the above-described alkali developer X-W1 means an alkali developer obtained by passing the alkali developer through the POU filter. Therefore, in the above-described procedure for removing the coating film, the alkali developer X-W1 which was the removal liquid after the filtration was applied onto the silicon wafer.

As a specific procedure for removing the coating film, a removal liquid connected to a development line of a coater by the above-described method was applied (discharged for 30 seconds at a flow rate of 600 mL/min) onto a surface of the silicon wafer with a coating film, on which the coating film had been formed, by a coater, and then baked at 100° C. for 60 seconds to obtain a coating film-removed substrate.

With the coating film-removed substrate, the number of metal atoms on the substrate was measured on a surface of the silicon wafer on which the coating film had been formed, using a total reflection X-ray fluorescence analyzer. The number of metal atoms per unit area on the substrate was calculated from the measurement results and an area value of the 8-inch (diameter: 200 mm) silicon wafer.

Hereinafter, “the number of metal atoms per unit area on the substrate” will also be referred to as “the number of metal atoms”.

### Comparative Example 1: Formation of Coating Film (with Exposure)

A silicon wafer with a coating film was produced according to the same procedure as that of Example 1.

Next, using a KrF excimer laser immersion scanner (manufactured by ASML; PAS5500/850C), the entire surface of the silicon wafer with a coating film was exposed with an exposure amount of 50 mJ/cm² in an open frame.

Thereafter, the silicon wafer with a coating film was heated (PEB) at 130° C. for 60 seconds, alkali-developed in a tetramethylammonium hydroxide aqueous solution (2.38% by mass) for 30 seconds, rinsed with pure water, and spin-dried. By the above-described entire surface exposure and alkali development treatment, the residual film (the cured film of the coating film) was formed on the entire surface of the substrate.

With the obtained substrate, in a case where the number of metal atoms on the substrate was measured on a surface of the silicon wafer on which the residual film had been formed, using a total reflection X-ray fluorescence analyzer, the metal atoms could not be detected.

The results of Examples 1 and Comparative Example 1 are collectively shown below.

Tables 1 to 9 shown below are described as follows.

In the tables, “Negative” in the column of “Type of composition” indicates that the composition is a negative tone photosensitive composition, and “Positive” indicates that the composition is a positive tone photosensitive composition.

In the column of “Intentional addition of metal components” of the tables, in a case where the metal compound containing the metal atoms (in the photosensitive composition A-1A, corresponding to the iron stearate (III)) was intentionally used in the preparation of the photosensitive composition, it is indicated as “Y”, and in a case of not being used, it is indicated as “N”.

In the column of “Exposure treatment after coating” of the tables, in a case where the exposure treatment was performed on the coating film, it is indicated as “Y”, and in a case of not being performed, it is indicated as “N”.

In the column of “Type of removal liquid” of Table 1, in a case where the alkali developer (alkali developer X-W1) was used, it is indicated as “Alkali”, and in a case where the organic solvent was used, it is indicated as “Solvent”.

In the tables, the description in the column of “Liquid type” is as follows.
TMAH: tetramethylammonium hydroxide
ER6: mixed solvent of PGMEA and PGME (mass ratio of PGMEA and PGME (PGMEA/PGME)=6/4)
CHN: cyclohexanone
nBA: butyl acetate

In the tables, the column of “Presence or absence of residual film” indicates whether or not the residual film (the cured film of the coating film) was present on the substrate on which the total reflection X-ray fluorescence analysis was performed, and a case where the residual film was present is indicated as “Y” and a case where the residual film was not present is indicated as “N”.

In the column of “Detection by total reflection X-ray fluorescence analysis method” of the tables, a case where the number of metal atoms could be measured is indicated as “Detectable”, and a case where the number of metal atoms could not be measured is indicated as “Undetectable”.

TABLE 1

| | | | Comparative |
|---|---|---|---|
| | | Example 1 | Example 1 |
| Composition | Type of composition | A-1A | A-1A |
| | | Negative | Negative |
| | Intentional addition of metal components | Y | Y |
| Exposure | Exposure treatment after coating | N | Y |
| Removal | Type of removal liquid | Alkali | Alkali |
| | Liquid type | TMAH | TMAH |
| | Treatment time of treatment using removal liquid (sec) | 30 | 30 |
| Residual | Presence or absence of residual film | N | Y |
| film | | | |
| Evaluation | Detection by total reflection X-ray fluorescence analysis | Detectable | Undetectable |
| | method | | |

As shown in Table 1, in Example 1 in which the coating film was not exposed, the metal atoms could be detected, but in Comparative Example 1 in which the coating film was exposed, the metal atoms could not be detected. In a case where the residual film was present on the substrate as shown in Comparative Example 1, it is presumed that the metal atoms could not be detected because the X-ray was not reflected or the reflectivity was significantly reduced.

### Example 2

The number of metal atoms was measured according to the same procedure as in Example 1, except that the photosensitive composition A-1 was used instead of the photosensitive composition A-1A.

### Example 3

The number of metal atoms was measured according to the same procedure as in Example 2, except that, after performing the treatment of removing the coating film using the removal liquid, a dry etching treatment using CF₄ was further performed on the surface of the silicon wafer from which the coating film had been removed for the time shown in Table 2.

### Example 4

The number of metal atoms was measured according to the same procedure as in Example 2, except that ER6 [mixed solvent of PGMEA and PGME (mass ratio of PGMEA and PGME (PGMEA/PGME)=6/4)] was used instead of the alkali developer X-W1.

### Example 5

The number of metal atoms was measured according to the same procedure as in Example 3, except that ER6 was used instead of the alkali developer X-W1.

### Example 6

The number of metal atoms was measured according to the same procedure as in Example 2, except that, instead of the treatment of removing the coating film using the removal liquid (alkali developer X-W1), a dry etching treatment using CF₄ was performed for the time shown in Table 2 to remove the coating film.

### Example 7

The number of metal atoms was measured according to the same procedure as in Example 6, except that a photosensitive composition B-1 described below was used instead of the photosensitive composition A-1.

### (Photosensitive Composition B-1)

A photosensitive composition B-1 was prepared as a positive tone photosensitive composition by the following procedure.

### (Preparation of Photosensitive Composition B-1)

A photosensitive composition B-1 was prepared
by mixing the following components.

| | | |
|---|---|---|
| Resin P-4 shown below | 68.0 | parts by mass |
| Photoacid generator A-2 shown below | 19.0 | parts by mass |
| Photoacid generator B-1 shown below | 9.0 | parts by mass |
| Basic compound Q-4 shown below | 4.0 | parts by mass |

Solvent (mixed solvent consisting of
EL/PGME/PGMEA (mass ratio: 40/20/40)
amount at which concentration of solid
contents was 2.6% by mass

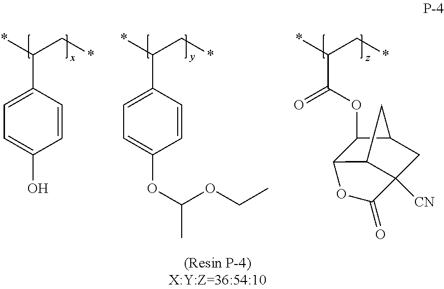

The numerical value shown for each repeating unit in the resin P-4 means a molar ratio. In addition, Mw of the resin P-4 was 5900, and Mw/Mn thereof was 1.5.

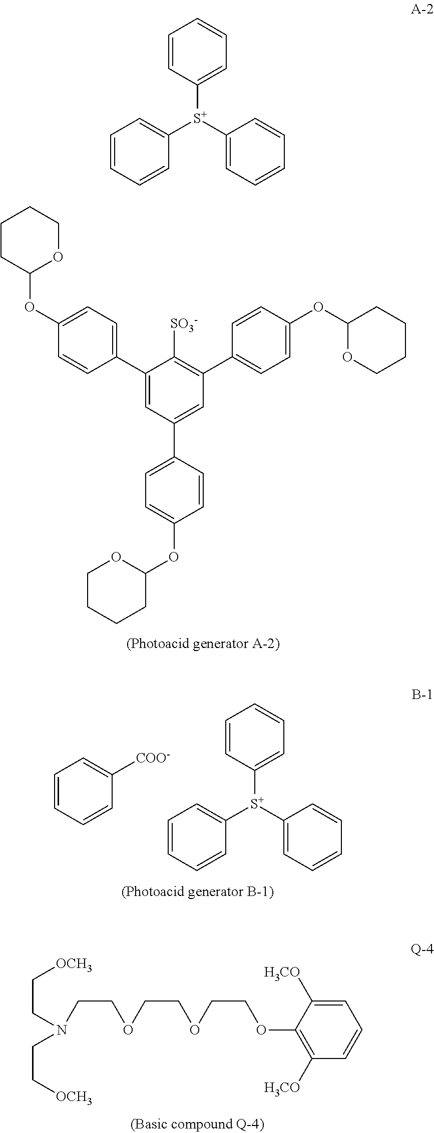

### (Filtration of Photosensitive Composition)

In addition, the photosensitive composition B-1 (12000 g) prepared by the above-described procedure was subjected to the following purification treatment, and the purified composition was used in Examples.

Specifically, the photosensitive composition B-1 was filtered through the following two-stage filter.

First stage: Nylon filter with a pore size of 5 nm, manufactured by PALL Corporation

Second stage: Polyethylene filter with a pore size of 1 nm, manufactured by Entegris

### Example 8

The number of metal atoms was measured according to the same procedure as in Example 2, except that a photosensitive composition C-1 shown below was used instead of the photosensitive composition A-1, and cyclohexanone (CHN) was used instead of the removal liquid (alkali developer X-W1).

### (Photosensitive Composition C-1)

Cyclohexanone (102.3 parts by mass) was heated to 80° C. under a nitrogen stream. While stirring the liquid, a mixed solution of a monomer represented by Structural Formula M-1 (22.2 parts by mass), a monomer represented by Structural Formula M-2 (22.8 parts by mass), a monomer represented by Structural Formula M-3 (6.6 parts by mass), cyclohexanone (189.9 parts by mass), and 2.40 parts by mass of dimethyl 2,2′-azobisisobutyrate [V-601 manufactured by FUJIFILM Wako Pure Chemical Corporation] was added dropwise thereto over 5 hours. After the completion of the dropwise addition, the mixture was further stirred at 80° C. for 2 hours. The reaction solution was left to be cooled, reprecipitated with a large amount of hexane/ethyl acetate (mass ratio: 9:1), and then filtered to collect precipitate, and the obtained solid was vacuum-dried to obtain 41.1 parts by mass of an acid-decomposable resin (A-1).

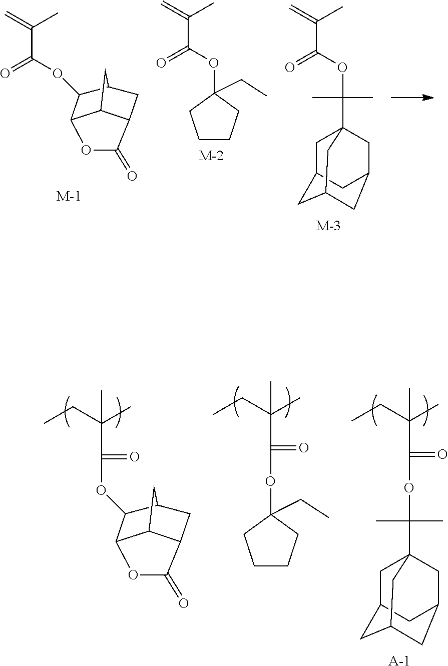

The obtained acid-decomposable resin (A-1) had a weight-average molecular weight (Mw; in terms of polystyrene) of 9,500 and a dispersity Mw/Mn of 1.60, as determined from GPC (carrier: tetrahydrofuran (THF)). A compositional ratio (molar ratio) measured by ¹³C-NMR was 40/50/10 in order from the structure on the left side.

Next, a photosensitive composition C-1 was prepared by mixing each of components shown below.

| | | |
|---|---|---|
| Acid-decomposable resin (resin A-1 described above) | 1,267 | g |
| Photoacid generator (PAG-7 shown below) | 101 | g |
| Quencher (C-1 shown below) | 22 | g |
| Hydrophobic resin (P′-5 shown below) | 10 | g |
| PGMEA | 38,600 | g |

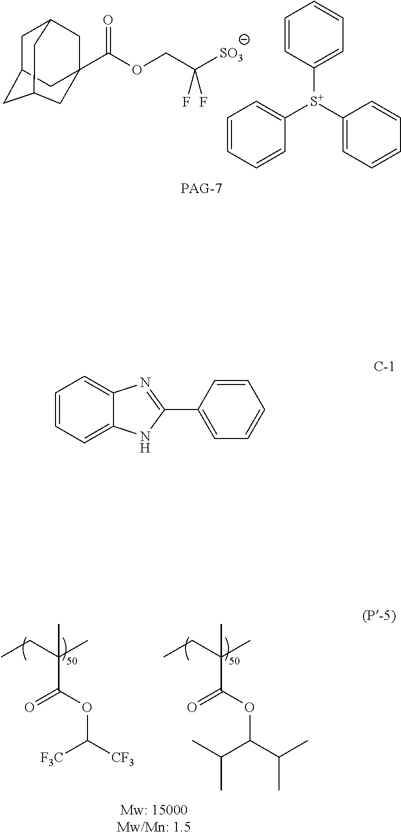

The numerical value shown for each repeating unit in the hydrophobic resin (P′-5) means a molar ratio.

In addition, the photosensitive composition C-1 prepared by the above-described procedure was subjected to the following filtration treatment, and the purified composition was used in Examples.

The photosensitive composition (12000 g) was filtered through the following two-stage filter.

First stage: Nylon filter with a pore size of 5 nm, manufactured by PALL Corporation

Second stage: Polyethylene filter with a pore size of 1 nm, manufactured by Entegris

### Example 9

The number of metal atoms was measured according to the same procedure as in Example 8, except that butyl acetate (nBA) was used instead of cyclohexanone (CHN).

In addition, in the column of “Gas removal” in Tables 2 to 9, a case where the dry etching treatment or the removal treatment of the coating film by the dry etching treatment was performed using the gas described in the column of “Gas type” is indicated as “Y”

TABLE 2

| | | Example 2 | Example 3 | Example 4 | Example 5 | Example 6 | Example 7 | Example 8 | Example 9 |
|---|---|---|---|---|---|---|---|---|---|
| Composition | Type of | A-1 | A-1 | A-1 | A-1 | A-1 | B-1 | C-1 | C-1 |
| | composition | Negative | Negative | Negative | Negative | Negative | Positive | Positive | Positive |
| | Intentional | N | N | N | N | N | N | N | N |
| | addition of metal | | | | | | | | |
| | components | | | | | | | | |
| Exposure | Exposure treatment | N | N | N | N | N | N | N | N |
| | after coating | | | | | | | | |
| Removal | Type of removal | Alkali | Alkali | Solvent | Solvent | — | — | Solvent | Solvent |
| | liquid | | | | | | | | |
| | Liquid type | TMAH | TMAH | ER6 | ER6 | — | — | CHN | nBA |
| | Treatment time of | 30 | 30 | 30 | 30 | — | — | 30 | 30 |
| | treatment using | | | | | | | | |
| | removal liquid | | | | | | | | |
| | (sec) | | | | | | | | |
| | Gas removal | — | Y | — | Y | Y | Y | — | — |
| | Gas type | — | CF₄ | — | CF₄ | CF₄ | CF₄ | — | — |
| | Treatment time of | — | 30 | — | 30 | 45 | 45 | — | — |
| | gas removal | | | | | | | | |
| | treatment (sec) | | | | | | | | |
| Residual | Residual film | N | N | N | N | N | N | N | N |
| film | | | | | | | | | |
| Evaluation | Detection by total | Detectable | Detectable | Detectable | Detectable | Detectable | Detectable | Detectable | Detectable |
| | reflection X-ray | | | | | | | | |
| | fluorescence | | | | | | | | |
| | analysis method | | | | | | | | |

As shown in Table 2, it was confirmed that the desired effects were obtained even in a case where the method of the treatment for removing the coating film was changed. In the photosensitive composition A-1 used in Example 2, the metal atoms could be detected even though the metal component was not intentionally added. It is presumed that a trace amount of metal atoms contained in raw materials used in the preparation of the photosensitive composition or a trace amount of metal atoms mixed in the preparation of the photosensitive composition was detected.

### Examples 11 and 12

The number of metal atoms was measured according to the same procedure as in Example 2, except that the treatment time of the treatment of removing the coating film using the removal liquid was changed to the time shown in the column of “Treatment time of treatment using removal liquid” in Table 3.

### Example 13

An aqueous solution containing 2% by mass of hydrogen peroxide and 2% by mass of hydrogen fluoride was dropped on the coating film-removed substrate, and the aqueous solution was allowed to be aggregated near the center of the substrate while scanning the substrate, and then dried by evaporation. The number of metal atoms was measured according to the same procedure as in Example 2, except that, with the substrate, the number of metal atoms on the substrate was measured by the total reflection X-ray fluorescence analysis method in the same manner as described above to obtain a measured value.

### Examples 14 and 15

The number of metal atoms was measured according to the same procedure as in Example 13, except that the treatment time of the treatment of removing the coating film using the removal liquid was changed to the time shown in the column of “Treatment time of treatment using removal liquid” in Table 3.

### Examples 16 and 17

The number of metal atoms was measured according to the same procedure as in Example 3, except that, after performing the treatment of removing the coating film using the removal liquid, the treatment time of the dry etching treatment (gas removal treatment) using CF₄ on the surface of the silicon wafer on which the coating film had been removed was changed to the time shown in the column of “Treatment time of gas removal treatment” in Table 3.

### Example 18

An aqueous solution containing 2% by mass of hydrogen peroxide and 2% by mass of hydrogen fluoride was dropped on the coating film-removed substrate, and the aqueous solution was allowed to be aggregated near the center of the substrate while scanning the substrate, and then dried by evaporation. The number of metal atoms was measured according to the same procedure as in Example 3, except that, with the substrate, the number of metal atoms on the substrate was measured by the total reflection X-ray fluorescence analysis method in the same manner as described above to obtain a measured value.

### Examples 19 and 20

The number of metal atoms was measured according to the same procedure as in Example 18, except that the treatment time of the gas removal treatment was changed to the time shown in the column of “Treatment time of gas removal treatment” in Table 3.

In Examples 11 to 20, each operation was performed five times to evaluate the variation in measured values of the number of metal atoms.

A case where the variation was small was evaluated as “A”, a case where the variation was slightly large was evaluated as “B”, a case where the variation was somewhat large was evaluated as “C”, and a case where the variation was large was evaluated as “D”.

In the column of “Concentration integration” in Table 3, a case where a concentration operation using the aqueous solution containing hydrogen fluoride and hydrogen peroxide (an operation of dropping the aqueous solution containing hydrogen fluoride and hydrogen peroxide, aggregating the aqueous solution near the center of the substrate while scanning the substrate, and then evaporating and drying the aqueous solution) was performed is indicated as “Y”.

In Table 3, the column of “Residual metal amount on wafer” indicates the results showing a relative relationship of the number of metal atoms in a case where the total reflection X-ray fluorescence analysis method was performed. Specifically, the number of metal atoms in Examples 11 and 12 is expressed as a relative amount using the number of metal atoms in Example 2 as a reference (ref1), the number of metal atoms in Examples 14 and 15 is expressed as a relative amount using the number of metal atoms in Example 13 as a reference (ref2), the number of metal atoms in Examples 16 and 17 is expressed as a relative amount using the number of metal atoms in Example 3 as a reference (ref3), and the number of metal atoms in Examples 19 and 20 is expressed as a relative amount using the number of metal atoms in Example 18 as a reference (ref4), in which “Medium” indicates a range of 0.3 to 0.7 times the reference value and “Small” indicates less than 0.3 times the reference value. “Medium (numerical value)” and “Small (numerical value)” indicate that the reference data of the numerical value in parentheses is used as a reference. For example, “Medium (1)” indicates data based on the ref1.

In Table 3, the column of “direct-TXRF” indicates the result of the total reflection X-ray fluorescence analysis method performed without performing the above-described treatment of “Concentration integration”, and the column of “After concentration integration-TXRF” indicates the result of the total reflection X-ray fluorescence analysis method performed in a case where the above-described treatment of “Concentration integration” was performed.

TABLE 3

| | | | Exam- | Exam- | Exam- | Exam- | Exam- | Exam- | Exam- |
|---|---|---|---|---|---|---|---|---|---|
| | | | ple 2 | ple 11 | ple 12 | ple 13 | ple 14 | ple 15 | ple 3 |
| Composition | Type of composition | | A-1 | A-1 | A-1 | A-1 | A-1 | A-1 | A-1 |
| | | | Negative | Negative | Negative | Negative | Negative | Negative | Negative |
| | Intentional addition of metal | | N | N | N | N | N | N | N |
| | components | | | | | | | | |
| Exposure | Exposure treatment after coating | | N | N | N | N | N | N | N |
| Removal | Type of removal liquid | | Alkali | Alkali | Alkali | Alkali | Alkali | Alkali | Alkali |
| | Liquid type | | TMAH | TMAH | TMAH | TMAH | TMAH | TMAH | TMAH |
| | Treatment time of treatment | | 30 | 60 | 300 | 30 | 60 | 300 | 30 |
| | using removal liquid (sec) | | | | | | | | |
| | Gas removal | | — | — | — | — | — | — | Y |
| | Gas type | | — | — | — | — | — | — | CF4 |
| | Treatment time of gas removal | | — | — | — | — | — | — | 30 |
| | treatment (sec) | | | | | | | | |
| Residual film | Residual film | | N | N | N | N | N | N | N |
| Concentration | Hydrogen fluoride + hydrogen | | — | — | — | Y | Y | Y | — |
| integration | peroxide | | | | | | | | |
| Evaluation | Residual metal amount on wafer | | ref1 | Medium | Small | ref2 | Medium | Small | ref3 |
| | | | | (1) | (1) | | (2) | (2) | |
| | direct-TXRF | Variation in | B | C | D | — | — | — | B |
| | | evaluation of | | | | | | | |
| | | 5 sheets | | | | | | | |
| | After | Variation in | — | — | — | A | A | B | — |
| | concentration | evaluation of | | | | | | | |
| | integration- | 5 sheets | | | | | | | |
| | TXRF | | | | | | | | |

| | | Exam- | Exam- | Exam- | Exam- | Exam- |
|---|---|---|---|---|---|---|
| | | ple 16 | ple 17 | ple 18 | ple 19 | ple 20 |
| Composition | Type of composition | A-1 | A-1 | A-1 | A-1 | A-1 |
| | | Negative | Negative | Negative | Negative | Negative |
| | Intentional addition of metal | N | N | N | N | N |
| | components | | | | | |
| Exposure | Exposure treatment after coating | N | N | N | N | N |
| Removal | Type of removal liquid | Alkali | Alkali | Alkali | Alkali | Alkali |
| | Liquid type | TMAH | TMAH | TMAH | TMAH | TMAH |
| | Treatment time of treatment | 30 | 30 | 30 | 30 | 30 |
| | using removal liquid (sec) | | | | | |
| | Gas removal | Y | Y | Y | Y | Y |
| | Gas type | CF₄ | CF₄ | CF₄ | CF₄ | CF₄ |
| | Treatment time of gas removal | 60 | 300 | 30 | 60 | 300 |
| | treatment (sec) | | | | | |
| Residual film | Residual film | N | N | N | N | N |
| Concentration | Hydrogen fluoride + hydrogen | — | — | Y | Y | Y |
| integration | peroxide | | | | | |
| Evaluation | Residual metal amount on wafer | Medium | Small | ref4 | Medium | Small |

| | | | | | | |
|---|---|---|---|---|---|---|
| | | (3) | (3) | | (4) | (4) |
| direct-TXRF | Variation in | C | D | — | — | — |
| | evaluation of | | | | | |
| | 5 sheets | | | | | |
| After | Variation in | — | — | A | A | B |
| concentration | evaluation of | | | | | |
| integration- | 5 sheets | | | | | |
| TXRF | | | | | | |

As shown in Table 3, as the removal time of the coating film (the treatment time of the treatment using the removal liquid or the treatment time of the gas removal treatment) increased, the residual metal amount on the wafer decreased, and the variation in measured values tended to increase.

Even in a case where the residual metal amount was reduced by performing the concentration operation (the step 5), the variation in measured values could be suppressed.

Each component was mixed based on the composition shown in Table 4 described below, thereby preparing photosensitive compositions D to N.

TABLE 4

| | | | | Photoacid | | Photoacid | | Basic | | | | Crosslinking | | | | Concen- |
|---|---|---|---|---|---|---|---|---|---|---|---|---|---|---|---|---|
| | | Resin | | generator 1 | | generator 2 | | compound | | Additive | | agent | | | | tration |
| | | | Part | | Part | | Part | | Part | | Part | | Part | | | of solid |
| | | | by | | by | | by | | by | | by | | by | Solvent | | contents |
| | Type | Type | mass | Type | mass | Type | mass | Type | mass | Type | mass | Type | mass | PGME | PGMEA | % by mass |
| D | Negative | P-8 | 57.7 | A-12 | 8.3 | B-1 | 5 | Q-1 | 1 | — | — | X-1 | 28 | 20 | 80 | 2.7 |
| | tone | | | | | | | | | | | | | | | |
| E | Negative | P-8 | 54.0 | A-13 | 10.8 | — | — | Q-3 | 5.9 | F-1 | 2.9 | X-1 | 26.4 | 20 | 80 | 2.7 |
| | tone | | | | | | | | | | | | | | | |
| F | Negative | P-8 | 54.1 | A-13 | 10.8 | — | — | Q-3 | 5.8 | F-2 | 2.9 | X-1 | 26.4 | 20 | 80 | 2.7 |
| | tone | | | | | | | | | | | | | | | |
| G | Negative | P-8 | 54.1 | A-13 | 10.8 | — | — | Q-3 | 5.8 | F-3 | 2.9 | X-1 | 26.4 | 20 | 80 | 2.7 |
| | tone | | | | | | | | | | | | | | | |
| H | Negative | P-8 | 56.8 | A-12 | 9.6 | — | — | Q-2 | 3.3 | F-1 | 2.9 | X-1 | 27.4 | 20 | 80 | 4.1 |
| | tone | | | | | | | | | | | | | | | |
| I | Negative | P-8 | 56.8 | A-12 | 9.6 | — | — | Q-2 | 3.3 | F-2 | 2.9 | X-1 | 27.4 | 20 | 80 | 4.1 |
| | tone | | | | | | | | | | | | | | | |
| J | Negative | P-8 | 56.8 | A-12 | 9.6 | — | — | Q-2 | 3.3 | F-3 | 2.9 | X-1 | 27.4 | 20 | 80 | 4.1 |
| | tone | | | | | | | | | | | | | | | |
| K | Negative | P-8 | 52.9 | A-12 | 14.5 | — | — | Q-4 | 6.1 | F-1 | 1.2 | X-1 | 25.3 | 20 | 80 | 2.8 |
| | tone | | | | | | | | | | | | | | | |
| L | Negative | P-8 | 52.8 | A-12 | 14.5 | — | — | Q-4 | 6.2 | F-2 | 1.2 | X-1 | 25.3 | 20 | 80 | 2.8 |
| | tone | | | | | | | | | | | | | | | |
| M | Negative | P-8 | 52.8 | A-12 | 14.5 | — | — | Q-4 | 6.2 | F-3 | 1.2 | X-1 | 25.3 | 20 | 80 | 2.8 |
| | tone | | | | | | | | | | | | | | | |
| N | Negative | P-8 | 52.9 | A-12 | 14.5 | — | — | Q-4 | 6.1 | F-4 | 1.2 | X-1 | 25.3 | 20 | 80 | 2.8 |
| | tone | | | | | | | | | | | | | | | |

In Table 4, the column of “Solvent” indicates the content (% by mass) of each solvent in 100% by mass of the solvent.

In Table 4, the column of “Concentration of solid contents” indicates the concentration (% by mass) of the solid contents in the photosensitive composition.

In Table 4, the resin P-8, the photoacid generator A-12, the photoacid generator B-1, the basic compound Q-1, the crosslinking agent X-1, PGME, and PGMEA are as described above.

Other compounds in Table 4 are as follows.

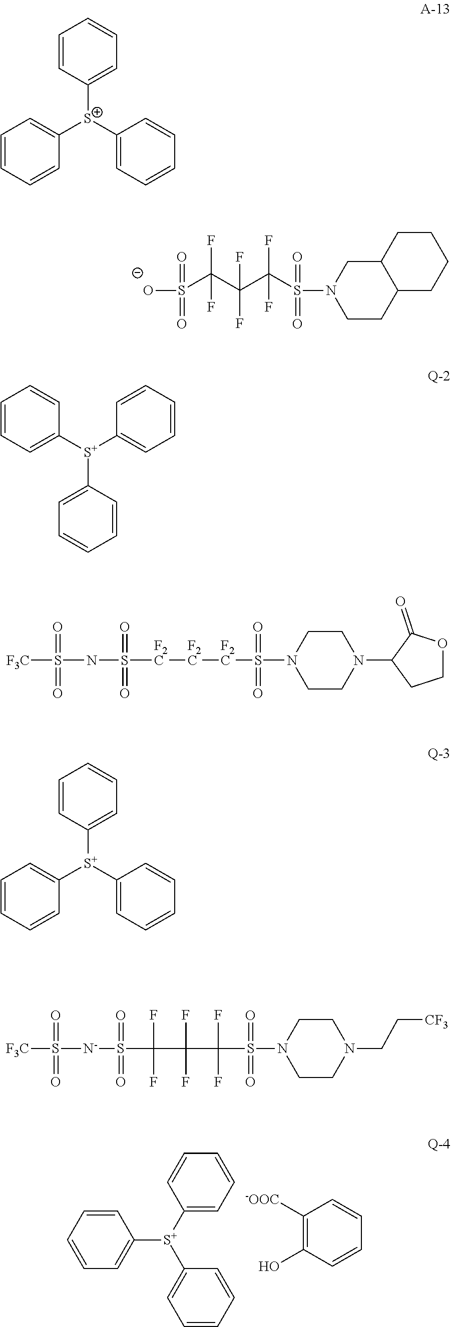

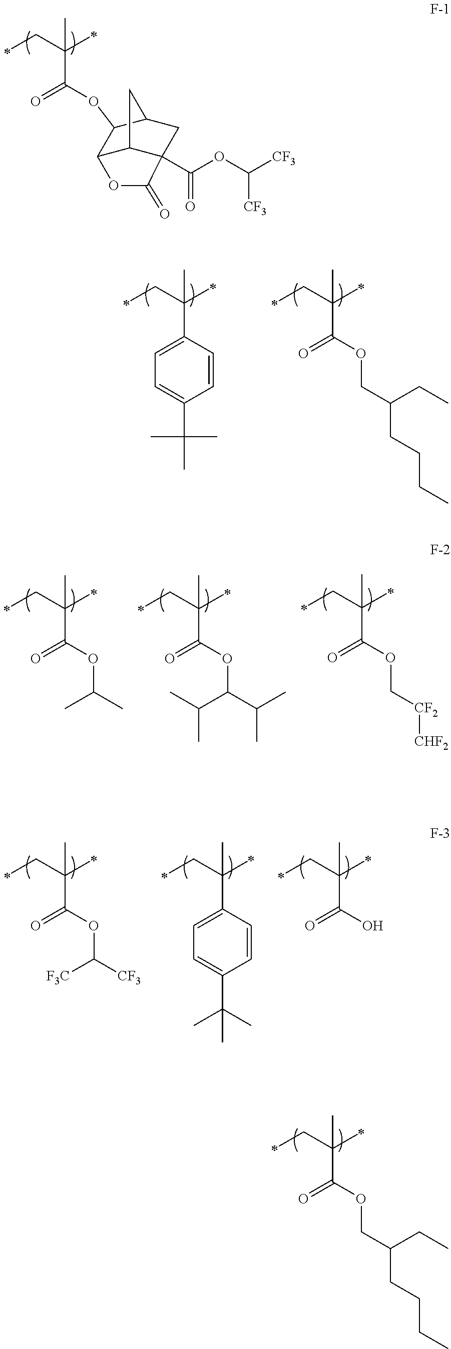

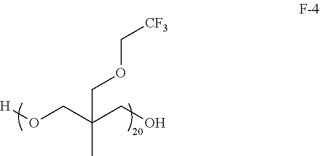

The content of each repeating unit with respect to all the repeating units in the above-described resin F-1 was 85% by mole, 10% by mole, and 5% by mole from the repeating unit on the left side.

The content of each repeating unit with respect to all the repeating units in the above-described resin F-2 was 30% by mole, 60% by mole, and 10% by mole from the repeating unit on the left side.

The content of each repeating unit with respect to all the repeating units in the above-described resin F-3 was 40% by mole, 50% by mole, 5% by mole, and 5% by mole from the repeating unit on the left side.

### Examples 21 to 31

The number of metal atoms was measured according to the same procedure as in Example 2, except that each of the photosensitive compositions D to N was used as shown in Table 5 instead of the photosensitive composition A-1.

### Examples 32 to 42

The number of metal atoms was measured according to the same procedure as in Example 13, except that each of the photosensitive compositions D to N was used as shown in Table 6 instead of the photosensitive composition A-1.

### Examples 43 to 53

The number of metal atoms was measured according to the same procedure as in Example 3, except that each of the photosensitive compositions D to N was used as shown in Table 7 instead of the photosensitive composition A-1.

### Examples 54 to 64

The number of metal atoms was measured according to the same procedure as in Example 18, except that each of the photosensitive compositions D to N was used as shown in Table 8 instead of the photosensitive composition A-1.

TABLE 5

| | | | Exam- | Exam- | Exam- | Exam- | Exam- | Exam- | Exam- |
|---|---|---|---|---|---|---|---|---|---|
| | | | ple 21 | ple 22 | ple 23 | ple 24 | ple 25 | ple 26 | ple 27 |
| Composition | Type of composition | | D | E | F | G | H | I | J |
| | | | Negative | Negative | Negative | Negative | Negative | Negative | Negative |
| | | | tone | tone | tone | tone | tone | tone | tone |
| | Intentional addition of metal | | N | N | N | N | N | N | N |
| | components | | | | | | | | |
| Exposure | Exposure treatment after | | N | N | N | N | N | N | N |
| | coating | | | | | | | | |
| Removal | Type of removal liquid | | Alkali | Alkali | Alkali | Alkali | Alkali | Alkali | Alkali |
| | Liquid type | | TMAH | TMAH | TMAH | TMAH | TMAH | TMAH | TMAH |
| | Treatment time of treatment | | 30 | 30 | 30 | 30 | 30 | 30 | 30 |
| | using removal liquid (sec) | | | | | | | | |
| | Gas removal | | — | — | — | — | — | — | — |
| | Gas type | | — | — | — | — | — | — | — |
| | Treatment time of gas removal | | — | — | — | — | — | — | — |
| | treatment (sec) | | | | | | | | |
| Residual film | Residual film | | N | N | N | N | N | N | N |
| Concentration | Hydrogen fluoride + hydrogen | | — | — | — | — | — | — | — |
| integration | peroxide | | | | | | | | |
| Evaluation | Residual metal amount on | | Same (1) | Same (1) | Same (1) | Same (1) | Same (1) | Same (1) | Same (1) |
| | wafer | | | | | | | | |
| | direct-TXRF | Variation in | B | B | B | B | B | B | B |
| | | evaluation of | | | | | | | |
| | | 5 sheets | | | | | | | |
| | After | Variation in | — | — | — | — | — | — | — |
| | concentration | evaluation of | | | | | | | |
| | integration- | 5 sheets | | | | | | | |
| | TXRF | | | | | | | | |

| | | Exam- | Exam- | Exam- | Exam- |
|---|---|---|---|---|---|
| | | ple 28 | ple 29 | ple 30 | ple 31 |
| Composition | Type of composition | K | L | M | N |
| | | Negative | Negative | Negative | Negative |
| | | tone | tone | tone | tone |
| | Intentional addition of metal | N | N | N | N |
| | components | | | | |
| Exposure | Exposure treatment after | N | N | N | N |
| | coating | | | | |
| Removal | Type of removal liquid | Alkali | Alkali | Alkali | Alkali |
| | Liquid type | TMAH | TMAH | TMAH | TMAH |
| | Treatment time of treatment | 30 | 30 | 30 | 30 |
| | using removal liquid (sec) | | | | |
| | Gas removal | — | — | — | — |
| | Gas type | — | — | — | — |
| | Treatment time of gas removal | — | — | — | — |
| | treatment (sec) | | | | |
| Residual film | Residual film | N | N | N | N |
| Concentration | Hydrogen fluoride + hydrogen | — | — | — | — |
| integration | peroxide | | | | |
| Evaluation | Residual metal amount on | Same (1) | Same (1) | Same (1) | Same (1) |
| | wafer | | | | |

| | | | | | |
|---|---|---|---|---|---|
| direct-TXRF | Variation in | B | B | B | B |
| | evaluation of | | | | |
| | 5 sheets | | | | |
| After | Variation in | — | — | — | — |
| concentration | evaluation of | | | | |
| integration- | 5 sheets | | | | |
| TXRF | | | | | |

TABLE 6

| | | | Exam- | Exam- | Exam- | Exam- | Exam- | Exam- |
|---|---|---|---|---|---|---|---|---|
| | | | ple 32 | ple 33 | ple 34 | ple 35 | ple 36 | ple 37 |
| Composition | Type of composition | | D | E | F | G | H | I |
| | | | Negative | Negative | Negative | Negative | Negative | Negative |
| | | | tone | tone | tone | tone | tone | tone |
| | Intentional addition of metal | | N | N | N | N | N | N |
| | components | | | | | | | |
| Exposure | Exposure treatment after | | N | N | N | N | N | N |
| | coating | | | | | | | |
| Removal | Type of removal liquid | | Alkali | Alkali | Alkali | Alkali | Alkali | Alkali |
| | Liquid type | | TMAH | TMAH | TMAH | TMAH | TMAH | TMAH |
| | Treatment time of treatment | | 30 | 30 | 30 | 30 | 30 | 30 |
| | using removal liquid (sec) | | | | | | | |
| | Gas removal | | — | — | — | — | — | — |
| | Gas type | | — | — | — | — | — | — |
| | Treatment time of gas removal | | — | — | — | — | — | — |
| | treatment (sec) | | | | | | | |
| Residual film | Residual film | | N | N | N | N | N | N |
| Concentration | Hydrogen fluoride + hydrogen | | Y | Y | Y | Y | Y | Y |
| integration | peroxide | | | | | | | |
| Evaluation | Residual metal amount on | | Same (2) | Same (2) | Same (2) | Same (2) | Same (2) | Same (2) |
| | wafer | | | | | | | |
| | direct-TXRF | Variation in | — | — | — | — | — | — |
| | | evaluation of | | | | | | |
| | | 5 sheets | | | | | | |
| | After | Variation in | A | A | A | A | A | A |
| | concentration | evaluation of | | | | | | |
| | integration- | 5 sheets | | | | | | |
| | TXRF | | | | | | | |

| | | Exam- | Exam- | Exam- | Exam- | Exam- |
|---|---|---|---|---|---|---|
| | | ple 38 | ple 39 | ple 40 | ple 41 | ple 42 |
| Composition | Type of composition | J | K | L | M | N |
| | | Negative | Negative | Negative | Negative | Negative |
| | | tone | tone | tone | tone | tone |
| | Intentional addition of metal | N | N | N | N | N |
| | components | | | | | |
| Exposure | Exposure treatment after | N | N | N | N | N |
| | coating | | | | | |
| Removal | Type of removal liquid | Alkali | Alkali | Alkali | Alkali | Alkali |
| | Liquid type | TMAH | TMAH | TMAH | TMAH | TMAH |
| | Treatment time of treatment | 30 | 30 | 30 | 30 | 30 |
| | using removal liquid (sec) | | | | | |
| | Gas removal | — | — | — | — | — |
| | Gas type | — | — | — | — | — |
| | Treatment time of gas removal | — | — | — | — | — |
| | treatment (sec) | | | | | |
| Residual film | Residual film | N | N | N | N | N |
| Concentration | Hydrogen fluoride + hydrogen | Y | Y | Y | Y | Y |
| integration | peroxide | | | | | |
| Evaluation | Residual metal amount on | Same (2) | Same (2) | Same (2) | Same (2) | Same (2) |
| | wafer | | | | | |

| | | | | | | |
|---|---|---|---|---|---|---|
| direct-TXRF | Variation in | — | — | — | — | — |
| | evaluation of | | | | | |
| | 5 sheets | | | | | |
| After | Variation in | A | A | A | A | A |
| concentration | evaluation of | | | | | |
| integration- | 5 sheets | | | | | |
| TXRF | | | | | | |

TABLE 7

| | | | Exam- | Exam- | Exam- | Exam- | Exam- | Exam- |
|---|---|---|---|---|---|---|---|---|
| | | | ple 43 | ple 44 | ple 45 | ple 46 | ple 47 | ple 48 |
| Composition | Type of composition | | D | E | F | G | H | I |
| | | | Negative | Negative | Negative | Negative | Negative | Negative |
| | | | tone | tone | tone | tone | tone | tone |
| | Intentional addition of metal | | N | N | N | N | N | N |
| | components | | | | | | | |
| Exposure | Exposure treatment after | | N | N | N | N | N | N |
| | coating | | | | | | | |
| Removal | Type of removal liquid | | Alkali | Alkali | Alkali | Alkali | Alkali | Alkali |
| | Liquid type | | TMAH | TMAH | TMAH | TMAH | TMAH | TMAH |
| | Treatment time of treatment | | 30 | 30 | 30 | 30 | 30 | 30 |
| | using removal liquid (sec) | | | | | | | |
| | Gas removal | | Y | Y | Y | Y | Y | Y |
| | Gas type | | CF₄ | CF₄ | CF₄ | CF₄ | CF₄ | CF₄ |
| | Treatment time of gas removal | | 30 | 30 | 30 | 30 | 30 | 30 |
| | treatment (sec) | | | | | | | |
| Residual film | Residual film | | N | N | N | N | N | N |
| Concentration | Hydrogen fluoride + hydrogen | | — | — | — | — | — | — |
| integration | peroxide | | | | | | | |
| Evaluation | Residual metal amount on | | Same (3) | Same (3) | Same (3) | Same (3) | Same (3) | Same (3) |
| | wafer | | | | | | | |
| | direct-TXRF | Variation in | B | B | B | B | B | B |
| | | evaluation of | | | | | | |
| | | 5 sheets | | | | | | |
| | After | Variation in | — | — | — | — | — | — |
| | concentration | evaluation of | | | | | | |
| | integration- | 5 sheets | | | | | | |
| | TXRF | | | | | | | |

| | | Exam- | Exam- | Exam- | Exam- | Exam- |
|---|---|---|---|---|---|---|
| | | ple 49 | ple 50 | ple 51 | ple 52 | ple 53 |
| Composition | Type of composition | J | K | L | M | N |
| | | Negative | Negative | Negative | Negative | Negative |
| | | tone | tone | tone | tone | tone |
| | Intentional addition of metal | N | N | N | N | N |
| | components | | | | | |
| Exposure | Exposure treatment after | N | N | N | N | N |
| | coating | | | | | |
| Removal | Type of removal liquid | Alkali | Alkali | Alkali | Alkali | Alkali |
| | Liquid type | TMAH | TMAH | TMAH | TMAH | TMAH |
| | Treatment time of treatment | 30 | 30 | 30 | 30 | 30 |
| | using removal liquid (sec) | | | | | |
| | Gas removal | Y | Y | Y | Y | Y |
| | Gas type | CF₄ | CF₄ | CF₄ | CF₄ | CF₄ |
| | Treatment time of gas removal | 30 | 30 | 30 | 30 | 30 |
| | treatment (sec) | | | | | |
| Residual film | Residual film | N | N | N | N | N |
| Concentration | Hydrogen fluoride + hydrogen | — | — | — | — | — |
| integration | peroxide | | | | | |
| Evaluation | Residual metal amount on | Same (3) | Same (3) | Same (3) | Same (3) | Same (3) |
| | wafer | | | | | |

| | | | | | | |
|---|---|---|---|---|---|---|
| direct-TXRF | Variation in | B | B | B | B | B |
| | evaluation of | | | | | |
| | 5 sheets | | | | | |
| After | Variation in | — | — | — | — | — |
| concentration | evaluation of | | | | | |
| integration- | 5 sheets | | | | | |
| TXRF | | | | | | |

TABLE 8

| | | | Exam- | Exam- | Exam- | Exam- | Exam- | Exam- |
|---|---|---|---|---|---|---|---|---|
| | | | ple 54 | ple 55 | ple 56 | ple 57 | ple 58 | ple 59 |
| Composition | Type of composition | | D | E | F | G | H | I |
| | | | Negative | Negative | Negative | Negative | Negative | Negative |
| | | | tone | tone | tone | tone | tone | tone |
| | Intentional addition of metal | | N | N | N | N | N | N |
| | components | | | | | | | |
| Exposure | Exposure treatment after | | N | N | N | N | N | N |
| | coating | | | | | | | |
| Removal | Type of removal liquid | | Alkali | Alkali | Alkali | Alkali | Alkali | Alkali |
| | Liquid type | | TMAH | TMAH | TMAH | TMAH | TMAH | TMAH |
| | Treatment time of treatment | | 30 | 30 | 30 | 30 | 30 | 30 |
| | using removal liquid (sec) | | | | | | | |
| | Gas removal | | Y | Y | Y | Y | Y | Y |
| | Gas type | | CF₄ | CF₄ | CF₄ | CF₄ | CF₄ | CF₄ |
| | Treatment time of gas removal | | 30 | 30 | 30 | 30 | 30 | 30 |
| | treatment (sec) | | | | | | | |
| Residual film | Residual film | | N | N | N | N | N | N |
| Concentration | Hydrogen fluoride + hydrogen | | Y | Y | Y | Y | Y | Y |
| integration | peroxide | | | | | | | |
| Evaluation | Residual metal amount on | | Same (4) | Same (4) | Same (4) | Same (4) | Same (4) | Same (4) |
| | wafer | | | | | | | |
| | direct-TXRF | Variation in | — | — | — | — | — | — |
| | | evaluation of | | | | | | |
| | | 5 sheets | | | | | | |
| | After | Variation in | A | A | A | A | A | A |
| | concentration | evaluation of | | | | | | |
| | integration- | 5 sheets | | | | | | |
| | TXRF | | | | | | | |

| | | Exam- | Exam- | Exam- | Exam- | Exam- |
|---|---|---|---|---|---|---|
| | | ple 60 | ple 61 | ple 62 | ple 63 | ple 64 |
| Composition | Type of composition | J | K | L | M | N |
| | | Negative | Negative | Negative | Negative | Negative |
| | | tone | tone | tone | tone | tone |
| | Intentional addition of metal | N | N | N | N | N |
| | components | | | | | |
| Exposure | Exposure treatment after | N | N | N | N | N |
| | coating | | | | | |
| Removal | Type of removal liquid | Alkali | Alkali | Alkali | Alkali | Alkali |
| | Liquid type | TMAH | TMAH | TMAH | TMAH | TMAH |
| | Treatment time of treatment | 30 | 30 | 30 | 30 | 30 |
| | using removal liquid (sec) | | | | | |
| | Gas removal | Y | Y | Y | Y | Y |
| | Gas type | CF₄ | CF₄ | CF₄ | CF₄ | CF₄ |
| | Treatment time of gas removal | 30 | 30 | 30 | 30 | 30 |
| | treatment (sec) | | | | | |
| Residual film | Residual film | N | N | N | N | N |
| Concentration | Hydrogen fluoride + hydrogen | Y | Y | Y | Y | Y |
| integration | peroxide | | | | | |
| Evaluation | Residual metal amount on | Same (4) | Same (4) | Same (4) | Same (4) | Same (4) |
| | wafer | | | | | |

| | | | | | | |
|---|---|---|---|---|---|---|
| direct-TXRF | Variation in | — | — | — | — | — |
| | evaluation of | | | | | |
| | 5 sheets | | | | | |
| After | Variation in | A | A | A | A | A |
| concentration | evaluation of | | | | | |
| integration- | 5 sheets | | | | | |
| TXRF | | | | | | |

In Tables 5 to 8, the column of “Residual metal amount on wafer” indicates the results showing a relative relationship of the number of metal atoms in a case where the total reflection X-ray fluorescence analysis method was performed. Specifically, the number of metal atoms in Examples 21 to 31 is expressed as a relative amount using the number of metal atoms in Example 2 as a reference (ref1), the number of metal atoms in Examples 32 to 42 is expressed as a relative amount using the number of metal atoms in Example 13 as a reference (ref2), the number of metal atoms in Examples 43 to 53 is expressed as a relative amount using the number of metal atoms in Example 3 as a reference (ref3), and the number of metal atoms in Examples 54 to 64 is expressed as a relative amount using the number of metal atoms in Example 18 as a reference (ref4), in which “Same” indicates a range of 0.9 to 1.1 times the reference value. “Same (numerical value)” indicates that the reference data of the numerical value in parentheses is used as a reference. For example, “Same (1)” indicates data based on the ref1.

As shown in Tables 5 to 8, the desired effects were obtained even in a case where the type of the photosensitive composition was changed.

Next, the number of defects was evaluated using the above-described photosensitive compositions A-1 to N.

Specifically, first, using a dark-field defect inspection apparatus SP5 manufactured by KLA-Tencor Corporation, defect inspection was performed on a 12-inch (diameter: 300 mm) silicon wafer used for inspection, and the number of defects with a size of 20 nm or more (number of defects) on the surface of the silicon wafer was measured (“EX: number of original substrate defects”).

In the measurement of the number of defects on the surface of the 12-inch (diameter: 300 mm) silicon wafer using the dark-field defect inspection apparatus SP5 manufactured by KLA-Tencor Corporation, which will be described below, an annular region of the 12-inch (diameter: 300 mm) silicon wafer, which was a concentric circle and had an area of 660 cm² (in other words, an annular region of a circle which was centered on the center of the 12-inch (diameter: 300 mm) silicon wafer and had an area of 660 cm²) was used as an inspection region.

In addition, in Table 9 described later, as a measurement result of the number of defects on the surface of the 12-inch (diameter: 300 mm) silicon wafer using the dark-field defect inspection apparatus SP5 manufactured by KLA-Tencor Corporation, the number of defects (unit: defects) and the number of defects per unit area (unit: defects/cm²) in the above-described annular region are indicated.

Next, each removal liquid used in Examples shown in Table 9 was connected to a line of a development of a coater of Clean Track ACT12 manufactured by Tokyo Electron Limited. In the connection, the above-described POU filter was connected to the connection pipe and used.

Subsequently, the removal liquid connected by the above-described method was applied (discharged for 30 seconds at a flow rate of 600 mL/min) onto the 12-inch (diameter: 300 mm) silicon wafer which had been inspected for the number of defects in advance as described above with a coater, and then baked at 100° C. for 60 seconds.

With the wafer after the application of the removal liquid obtained by the above-described procedure, using a dark-field defect inspection apparatus SP5 manufactured by KLA-Tencor Corporation, the number of defects with a size of 20 nm or more (number of defects) on the surface of the silicon wafer was measured (“F: number of defects after application of removal liquid”).

Next, “C: number of defects of removal liquid” was determined by the following expression, based on the results of “EX: number of original substrate defects” and “F: number of defects after application of removal liquid” obtained by the various inspections.

[C: number of defects of removal liquid]=[F: number of defects after application of removal liquid]−[EX: number of original substrate defects] Expression (A1):

Through the above-described inspections, it was confirmed that the initial number of defects of the removal liquid ([C: number of defects of removal liquid]) shown in Table 9 was 100 or less (0.15 defects/cm² or less) in terms of the number of defects.

Next, prior to a defect evaluation of a resist film, using the dark-field defect inspection apparatus SP5 manufactured by KLA-Tencor Corporation, defect inspection was performed on a 12-inch (diameter: 300 mm) silicon wafer used for inspection (wafer for inspection), and the number of defects with a size of 20 nm or more (number of defects) on the surface of the silicon wafer was measured (“E: number of original substrate defects”).

Each of the photosensitive compositions used in Examples was connected to a line of a resist of a coater of Clean Track ACT12 manufactured by Tokyo Electron Limited (in the connection, the connection pipe was not connected to the filter, and a dummy capsule was used).

Subsequently, the photosensitive composition connected by the above-described method was applied onto the above-described 12-inch (diameter: 300 mm) silicon wafer as the wafer for inspection with a coater, and then baked at 90° C. for 90 seconds to form a coating film. The film thickness of the resist film (coating film) at this time was adjusted to 80 nm. As described above, an exposure treatment was not performed in the above-described step. In addition, the substrate on which the resist film had been formed was stored in a wafer case in a clean room until the resist film was provided for the removal treatment described below.

Next, using each removal liquid shown in Table 9, the resist film was removed from the silicon wafer with a resist film, obtained by performing the above-described procedure. For example, in Example X1, a resist film formed of the photosensitive composition A-1 was removed using the removal liquid (alkali developer X-W1) which was an alkali developer. In addition, ER6 was used as the removal liquid in Example X2, and CHN was used as the removal liquid in Example X3.

The removal was carried out using Clean Track ACT12 manufactured by Tokyo Electron Limited, to which the removal liquid was connected. In the connection, the above-described POU filter was connected to the connection pipe and used.

As a specific procedure of the above-described removal, a removal liquid connected to a development line of a coater by the above-described method was applied (discharged for 30 seconds at a flow rate of 600 mL/min) onto the silicon wafer with a resist film by a coater, and then baked at 100° C. for 60 seconds.

With the wafer from which the resist film had been removed by the above-described treatment, using a dark-field defect inspection apparatus SP5 manufactured by KLA-Tencor Corporation, defect inspection was performed to measure the number of defects with a size of 20 nm or more (number of defects) on the surface of the silicon wafer (“D: total number of defects after solvent removal treatment”).

Next, “A: number of resist defects” was determined by the following expression, based on the results of “E: number of original substrate defects”, “D: total number of defects after solvent removal treatment”, and [C: number of defects of removal liquid] obtained by the various inspections.

[A: number of resist defects]=[D: total number of defects after solvent removal treatment]−[E: number of original substrate defects]−[C: number of defects of removal liquid] Expression:

The column of “Number of defects [defects]” in Table 9 indicates the value of the number of resist defects, expressed as [A: Number of resist defects], and the column of “Number of defects [defects/cm²]” indicates the value of the number of resist defects per unit area.

TABLE 9

| | | Exam- | Exam- | Exam- | Exam- | Exam- | Exam- | Exam- | Exam- |
|---|---|---|---|---|---|---|---|---|---|
| | | ple X1 | ple X2 | ple X3 | ple X4 | ple X5 | ple X6 | ple X7 | ple X8 |
| Type of photosensitive | | A-1 | B-1 | C-1 | D | E | F | G | H |
| composition | | Negative | Positive | Positive | Negative | Negative | Negative | Negative | Negative |
| | | tone | tone | tone | tone | tone | tone | tone | tone |
| Type of removal liquid | | Alkali | Solvent | Solvent | Alkali | Alkali | Alkali | Alkali | Alkali |
| | | | (ER6) | (CHN) | | | | | |
| Presence or absence of | | N | N | N | N | N | N | N | N |
| surfactant in removal liquid | | | | | | | | | |
| Evaluation | Number of | 439 | 421 | 449 | 450 | 425 | 430 | 435 | 432 |
| of number | defects | | | | | | | | |
| of defects | [defects] | | | | | | | | |
| | Number of | 0.67 | 0.64 | 0.68 | 0.68 | 0.64 | 0.65 | 0.66 | 0.65 |
| | defects | | | | | | | | |
| | [defects/cm²] | | | | | | | | |

| | | Exam- | Exam- | Exam- | Exam- | Exam- | Exam- |
|---|---|---|---|---|---|---|---|
| | | ple X9 | ple X10 | ple X11 | ple X12 | ple X13 | ple X14 |
| Type of photosensitive | | I | J | K | L | M | N |
| composition | | Negative | Negative | Negative | Negative | Negative | Negative |
| | | tone | tone | tone | tone | tone | tone |
| Type of removal liquid | | Alkali | Alkali | Alkali | Alkali | Alkali | Alkali |
| Presence or absence of | | N | N | N | N | N | N |
| surfactant in removal liquid | | | | | | | |
| Evaluation | Number of | 448 | 451 | 452 | 446 | 444 | 439 |
| of number | defects | | | | | | |
| of defects | [defects] | | | | | | |
| | Number of | 0.68 | 0.68 | 0.68 | 0.68 | 0.67 | 0.67 |
| | defects | | | | | | |
| | [defects/cm²] | | | | | | |

What is claimed is:

1. An analysis method of a photosensitive composition, comprising:
a step 1 of applying a photosensitive composition onto a substrate to form a coating film;
a step 2 of removing the coating film from the substrate without exposing the coating film to obtain a coating film-removed substrate; and
a step 3 of measuring the number of metal atoms per unit area on the coating film-removed substrate by a total reflection X-ray fluorescence analysis method to obtain a measured value.

2. The analysis method of a photosensitive composition according to claim 1, further comprising, between the step 2 and the step 3:
a step 4 of bringing a gas containing a hydrogen fluoride gas into contact with the coating film-removed substrate.

3. The analysis method of a photosensitive composition according to claim 1, further comprising, between the step 2 and the step 3:
a step 5 of scanning the coating film-removed substrate with a solution containing hydrogen fluoride and hydrogen peroxide to collect metal atoms in the coating film-removed substrate in the solution.

4. The analysis method of a photosensitive composition according to claim 1,
wherein, in the step 2, the coating film is removed using a solution.

5. The analysis method of a photosensitive composition according to claim 4,
wherein the solution is selected from the group consisting of an aqueous solution containing tetramethylammonium hydroxide, an ester-based organic solvent, an alcohol-based organic solvent, and a ketone-based organic solvent.

6. The analysis method of a photosensitive composition according to claim 4,
wherein the solution is selected from the group consisting of propylene glycol monomethyl ether acetate, propylene glycol monomethyl ether, methyl amyl ketone, cyclohexanone, ethyl lactate, butyl acetate, and γ-butyrolactone.

7. The analysis method of a photosensitive composition according to claim 4,
wherein, in the step 2, a removal time of the coating film is 300 seconds or less.

8. The analysis method of a photosensitive composition according to claim 7,
wherein the removal time of the coating film is 180 seconds or less.

9. The analysis method of a photosensitive composition according to claim 1,
wherein, in the step 2, the coating film is removed using a gas.

10. The analysis method of a photosensitive composition according to claim 9,
wherein the gas is selected from the group consisting of a fluorine-based gas, an oxygen-based gas, and a rare gas.

11. The analysis method of a photosensitive composition according to claim 9,
wherein, in the step 2, a removal time of the coating film is 300 seconds or less.

12. The analysis method of a photosensitive composition according to claim 11,
wherein a removal time of the coating film is 180 seconds or less.

13. A production method of a photosensitive composition, comprising:
a step of preparing a photosensitive composition; and
a step of performing the analysis method according to claim 1 on the prepared photosensitive composition.

14. A manufacturing method of an electronic device, comprising:
a step of performing the analysis method according to claim 1.

15. The analysis method of a photosensitive composition according to claim 2, further comprising, between the step 2 and the step 3:
a step 5 of scanning the coating film-removed substrate with a solution containing hydrogen fluoride and hydrogen peroxide to collect metal atoms in the coating film-removed substrate in the solution.

16. The analysis method of a photosensitive composition according to claim 2,
wherein, in the step 2, the coating film is removed using a solution.

17. The analysis method of a photosensitive composition according to claim 16,
wherein the solution is selected from the group consisting of an aqueous solution containing tetramethylammonium hydroxide, an ester-based organic solvent, an alcohol-based organic solvent, and a ketone-based organic solvent.

18. The analysis method of a photosensitive composition according to claim 5,
wherein the solution is selected from the group consisting of propylene glycol monomethyl ether acetate, propylene glycol monomethyl ether, methyl amyl ketone, cyclohexanone, ethyl lactate, butyl acetate, and γ-butyrolactone.

19. The analysis method of a photosensitive composition according to claim 5,
wherein, in the step 2, a removal time of the coating film is 300 seconds or less.

20. The analysis method of a photosensitive composition according to claim 19,
wherein the removal time of the coating film is 180 seconds or less.
